(19) United States
(12) Patent Application Publication
(10) Pub. No.: US 2026/0333848 A1
(43) Pub. Date: Oct. 22, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Ruei-Jyun HSU, Hsinchu City (TW); Chen-Kang JIANG, Taipei City (TW); Jheng-Yi JIANG, Hsinchu City (TW); Wei-Jen CHANG, Miaoli County (TW); Chih-Pin HUNG, Hsinchu City (TW); Hung-Han LIN, Hsinchu City (TW)

(21) Appl. No.: 19/181,966

(22) Filed: Apr. 17, 2025

(51) Int. Cl. H10D 84/80; G05F 3/26; H10D 1/43; H10D 30/47; H10D 84/01

(52) U.S. Cl. CPC H10D 84/817; H10D 84/0123; G05F 3/26; H10D 1/43; H10D 30/471

(57) ABSTRACT

A semiconductor device may be manufactured to include a semiconductor structure in which a current mirror circuit is implemented. The semiconductor structure may be manufactured so that the current mirror circuit includes one or more variable resistor structures. For example, the semiconductor structure may be manufactured so that the current mirror circuit includes a variable reference resistor structure and/or a variable output resistor structure. The variable resistor structures may be manufactured using gallium (Ga) based high electron mobility transistor (HEMT)-like processes. This enables the manufacturing of the variable resistor structures to be easily integrated with manufacturing of the transistors of the current mirror circuit, which reduces manufacturing process complexity, cost, and/or time for integrating the variable resistor structures into the current mirror circuit.

### BACKGROUND

A current mirror circuit is a building block in analog electronics used to copy (or mirror) a reference current to another part of a circuit. Current mirror circuits may be used in biasing applications, current source circuits, and situations where a stable current is to be replicated.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example schematic of a circuit described herein.

FIGS. 2A-2G are diagrams of an example circuit structure of a circuit described herein.

FIGS. 3A-3P are diagrams of an example implementation of forming a circuit structure described herein.

FIGS. 4A-4G are diagrams of an example circuit structure of a circuit described herein.

FIGS. 5A-5D are diagrams of an example circuit structure of a circuit described herein.

FIGS. 6A-6D are diagrams of an example circuit structure of a circuit described herein.

FIG. 7 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In an electronic power supply, a current mirror circuit can be used to provide a stable reference current for voltage regulation, current limiting, and/or power supply biasing, among other examples. For example, an electronic power supply may include a voltage regulator, and a current mirror circuit of the power supply may be used to generate a reference current that is used to set and stabilize the output voltage of the voltage regulator. The current mirror circuit may ensure that the electrical current that is supplied to various stages or loads of the power supply remains constant and well-controlled, even as conditions such as load changes and/or voltage fluctuations occur.

Variation in a semiconductor fabrication process for a current mirror circuit can lead to adverse effects on the performance of the current mirror circuit. For example, variation in the semiconductor fabrication process for current mirror circuits may result in variation in threshold voltage across a plurality of current mirror circuits, resulting in variation in current mirroring across the current mirror circuits. This can lead to variation in performance across electronic power supplies and/or can lead to some power supplies not satisfying performance tolerances (e.g., electrical current tolerances).

In some implementations described herein, a semiconductor device may be manufactured to include a semiconductor structure in which a current mirror circuit is implemented. The semiconductor structure may be manufactured so that the current mirror circuit includes one or more variable resistor structures. For example, the semiconductor structure may be manufactured so that the current mirror circuit includes a variable reference resistor structure and/or a variable output resistor structure. The variable resistor structures may be manufactured using gallium (Ga) based high electron mobility transistor (HEMT)-like processes. This enables the manufacturing of the variable resistor structures to be easily integrated with manufacturing of the transistors of the current mirror circuit, which reduces manufacturing process complexity, cost, and/or time for integrating the variable resistor structures into the current mirror circuit.

The resistance of the variable reference resistor structure can be adjusted by applying a dynamic bias to the variable reference resistor structure, which enables the reference current of the current mirror circuit to be tunable. Similarly, the resistance of the variable output resistor structure can be adjusted by applying a dynamic bias to the variable output resistor structure, which enables the output current of the current mirror circuit to be tunable. This enables the reference current and/or the output current (e.g., the mirrored current) of the current mirror circuit to be tuned to compensate for variations in semiconductor manufacturing of the semiconductor device, to be adjusted for overclocking, and/or to be adjusted for other purposes.

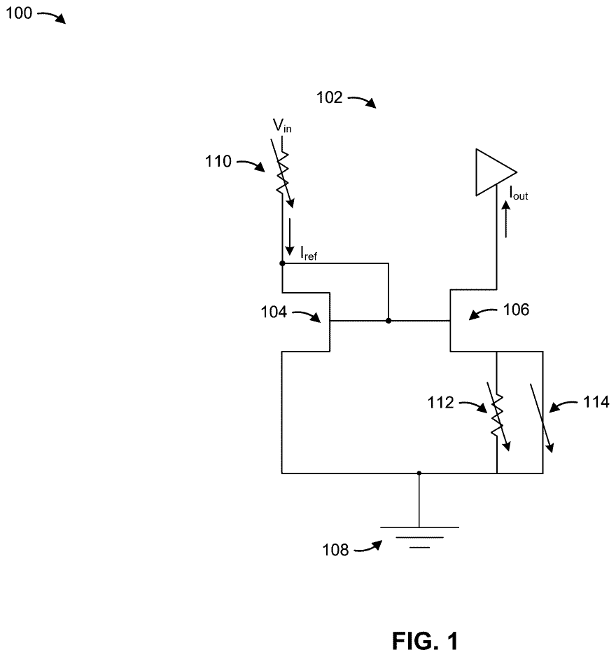

FIG. 1 is a diagram of an example schematic 100 of a circuit 102 described herein. The circuit 102 includes a current mirror circuit. The circuit 102 may be configured to copy a reference current (I_{ref}) one or more times to generate a stable output current (Iₒᵤₜ).

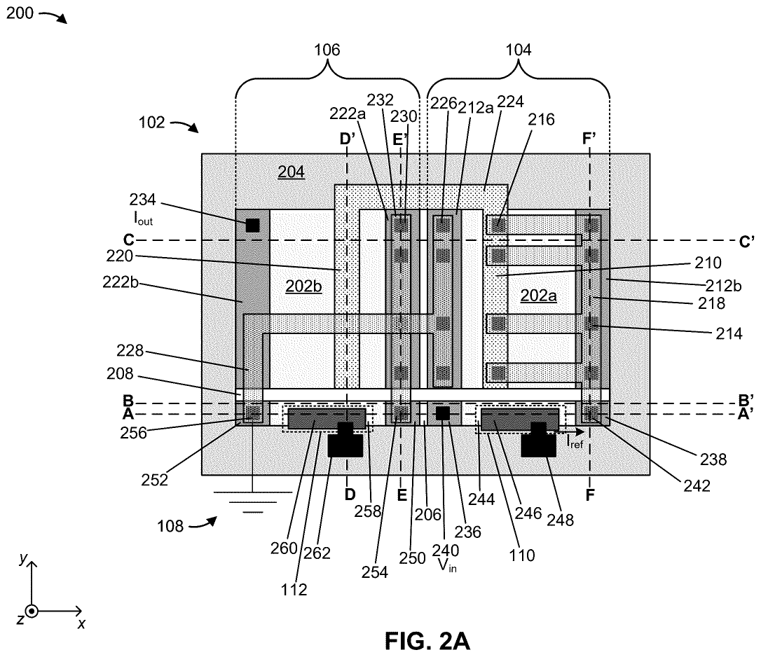

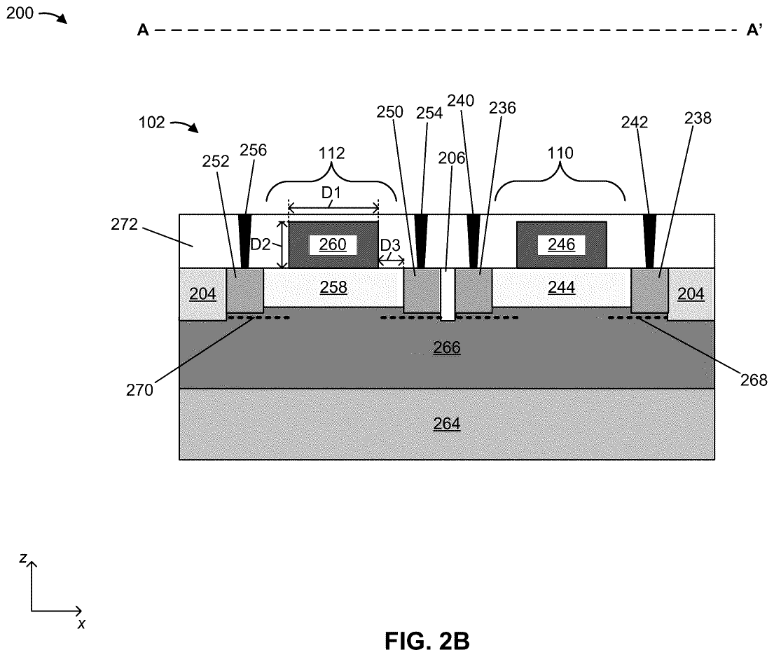

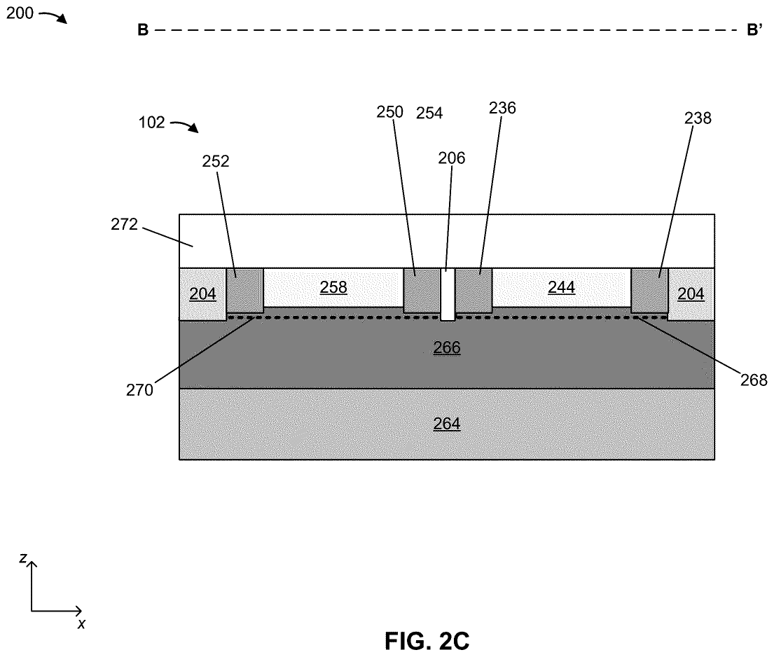

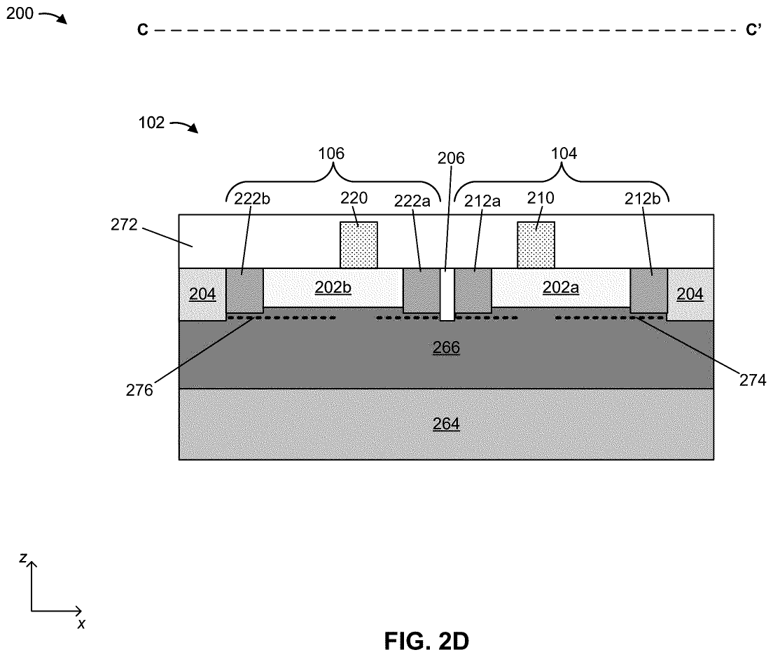

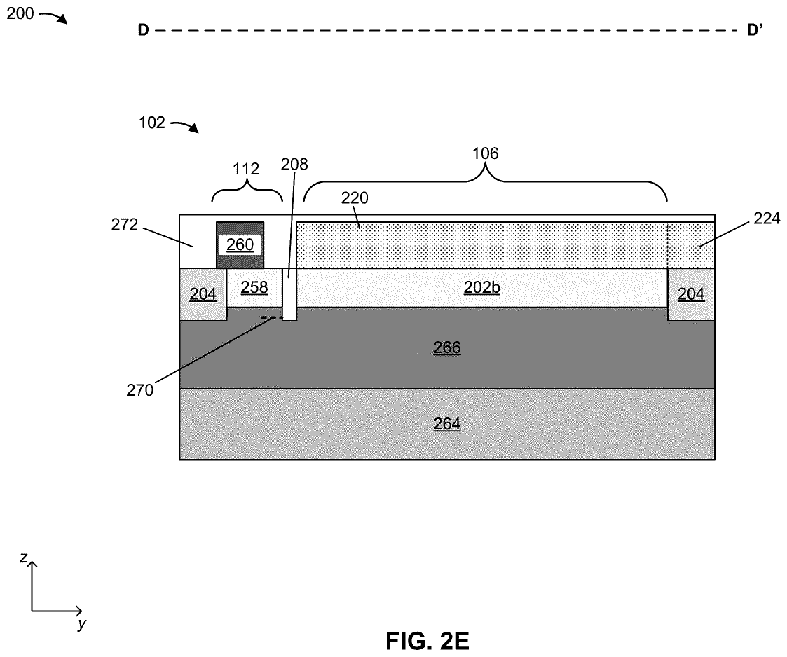

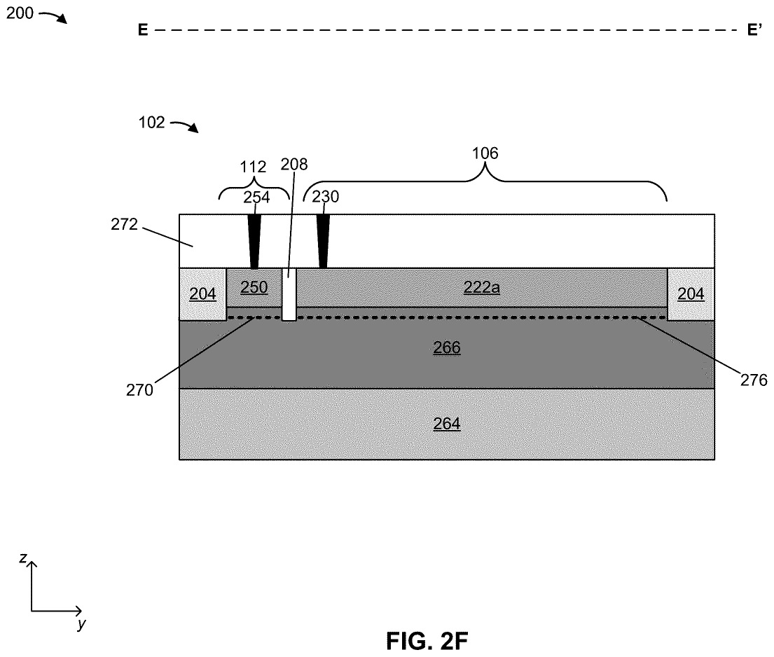

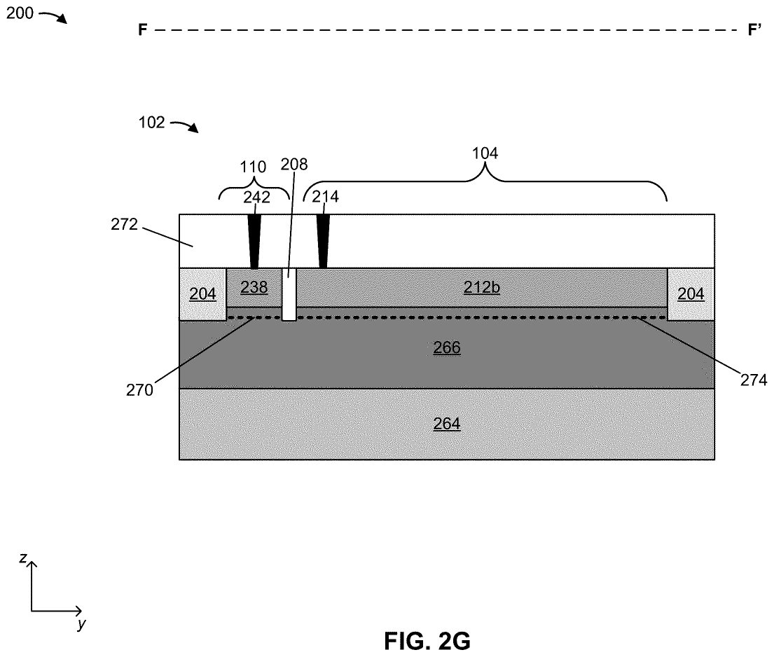

As shown in FIG. 1, the circuit 102 includes a plurality of transistors, such as a transistor 104 and a transistor 106. The transistor 104 may be referred to as the Q1 transistor or reference transistor of the current mirror circuit, and the transistor 106 may be referred to as the Q2 transistor or output transistor of the current mirror circuit. The transistor 104 and the transistor 106 may be matched transistors, such as bipolar junction transistors (BJTs) that have approximately the same base-emitter voltage, or metal-oxide-semiconductor field-effect transistors (MOSFETs) that have approximately the same gate-source voltage. In some implementations, the transistors 104 and 106 are implemented as HEMTs, as illustrated in an example in FIGS. 2A-2G.

As further shown in FIG. 1, first source/drains of the transistors 104 and 106 may be electrically coupled to an electrical ground 108. A source/drain may refer to a source or a drain, individually or collectively dependent upon the context. Grounding the transistors 104 and 106 ensures that the gate-source voltages of the transistors 104 and 106 remains approximately the same, which causes approximately a same electrical current (e.g., a mirrored current) to flow through both of the transistors 104 and 106.

As further shown in FIG. 1, the gates of the transistors 104 and 106 are electrically coupled together, and are electrically coupled to a second source/drain of the transistor 104. The gates and the second source/drain are electrically coupled to a variable resistor 110 of the circuit 102. An input voltage (Vᵢₙ) may be applied across the variable resistor 110, which provides the reference current (I_{ref}) to the gates of the transistors 104 and 106 and to the second source/drain of the transistor 104. The variable resistor 110 may be electrically coupled to a power supply such as a voltage source that provides the input voltage.

The gates of the transistors 104 and 106 being electrically coupled, and the transistors 104 and 106 having approximately the same gate-source voltages, enables the reference current (I_{ref}) to be mirrored from the transistor 104 to the transistor 106 as the output current (Iₒᵤₜ). The resistance of the variable resistor 110 is variable, which enables the variable resistor 110 to be used to tune or adjust the voltage drop across the variable resistor 110 (and thus, the reference current). In this way, variations in manufacturing (such as variations in feature sizes of the transistors 104 and/or 106) can be compensated for by adjusting the resistance of the variable resistor 110 to achieve a particular reference current (I_{ref}) (and thus, to achieve a particular output current (Iₒᵤₜ)). Additionally and/or alternatively, the ability to adjust the reference current (I_{ref}) (and thus, to adjust the output current (Iₒᵤₜ)) provides increased operational flexibility than if a fixed resistor were used, and enables the output current (Iₒᵤₜ) to be tuned for overclocking and other advanced techniques.

As described in greater detail in connection with FIGS. 2A-2G, the variable resistor 110 may be a three-terminal device, having an input terminal coupled to the power supply, an output terminal coupled to the transistors 104 and 106, and a bias terminal coupled to the body of the variable resistor 110. A voltage bias may be applied to the bias terminal to adjust or modify the resistivity of the body of the variable resistor 110.

In a similar manner, a variable resistor 112 may be electrically coupled between a second source/drain of the transistor 106 and the electrical ground 108 to provide for adjustability of the output current (Iₒᵤₜ). The resistance of the variable resistor 112 is variable, which enables the variable resistor 112 to be used to tune or adjust the voltage drop across the source/drains of the transistor 106 (and thus, the output current). In this way, variations in manufacturing (such as variations in feature sizes of the transistors 104 and/or 106) can be compensated for by adjusting the resistance of the variable resistor 112 to achieve an output current (Iₒᵤₜ). Additionally and/or alternatively, the ability to adjust the output current (Iₒᵤₜ) provides increased operational flexibility than if a fixed resistor were used, and enables the output current (Iₒᵤₜ) to be tuned for overclocking and other advanced techniques.

The output side of the circuit 102 may be electrically coupled to additional variable circuits 114, which may provide for further tuning of the output of the circuit 102 and/or may provide for tuning of the variable circuits 114.

As indicated above, FIG. 1 is provided as an example. Other examples may differ from what is described with regard to FIG. 1.

FIGS. 2A-2G are diagrams of an example circuit structure 200 of the circuit 102 described herein. In particular, the circuit structure 200 is an example of a circuit structure implementation of the circuit 102 in which the circuit 102 is implemented in a semiconductor device.

FIG. 2A illustrates a top view of the circuit structure 200 of the circuit 102. As shown in FIG. 2A, the transistors 104 and 106 of the circuit 102 may be implemented by transistor structures in the circuit structure 200. In the circuit structure 200, the transistors 104 and 106 are implemented as HEMT structures. However, in other implementations, the transistors 104 and/or 106 may be implemented by another type of transistor structure, such as a BJT structure and/or a MOSFET structure, among other examples. Moreover, the transistors 104 and 106 may be implemented as planar HEMT structures, fin field effect transistor (finFET) HEMT structures, nanostructure HEMT structures (e.g., gate-all-around (GAA) HEMT structures), and/or another type of HEMT structures.

As further shown in FIG. 2A, the transistors 104 and 106 may be laterally adjacent in an x-direction in the circuit structure 200. The transistor 104 and the variable resistor 110 may be laterally adjacent in a y-direction in the circuit structure 200, which may be approximately perpendicular to the x-direction. The transistor 106 and the variable resistor 112 may be laterally adjacent in the y-direction in the circuit structure 200. The variable resistors 110 and 112 may be laterally adjacent in the x-direction in the circuit structure 200.

The transistors 104 and 106 may respectively include active regions 202a and 202b. The active regions 202a and 202b may correspond to the portions of the circuit structure 200 in which the transistors 104 and 106 respectively operate. The active regions 202a and 202b may each include a semiconductor layer that contain a semiconductor material. In implementations in which the transistors 104 and 106 are implemented as p-type gallium nitride (GaN) (pGaN) HEMT structures, the active regions 202a and 202b may each contain a gallium nitride (GaN)-based material such as aluminum gallium nitride (AlGaN), among other examples. The aluminum gallium nitride may be in crystalline form in the active regions 202a and 202b. In implementations in which the transistors 104 and 106 are implemented as n-type HEMT structures, the active regions 202a and 202b may each contain a gallium arsenide (GaAs)-based material such as aluminum gallium arsenide (AlGaAs), among other examples.

As further shown in FIG. 2A, the active regions 202a and 202b respectively of the transistors 104 and 106 may be electrically isolated by various isolation regions in the circuit structure 200. For example, the circuit 102 (including the active regions 202a and 202b) may be surrounded by a circuit isolation structure 204. The circuit isolation structure 204 may include a shallow trench isolation (STI) structure that extends around two or more sides of the active regions 202a and 202b and contains one or more dielectric materials such as silicon oxide (SiOₓ) and/or silicon nitride (SiₓN_{y}), among other examples. Alternatively, the circuit isolation structure 204 may be a doped semiconductor region that is implanted with one or more types of dopants (e.g., p-type dopants, n-type dopants). Alternatively, the circuit isolation structure 204 may include amorphous isolation achieved by implanting oxygen.

As another example, the transistors 104 and 106 may be electrically isolated from each other by an isolation structure 206. The variable resistors 110 and 112 may also be electrically isolated from each other by the isolation structure 206. The isolation structure 206 may be elongated in, and may extend in, the y-direction laterally between the transistors 104 and 106. The isolation structure 206 may also extend laterally between the variable resistors 110 and 112. The isolation structure 206 may include an STI structure that contains one or more dielectric materials such as silicon oxide (SiOₓ) and/or silicon nitride (SiₓN_{y}), among other examples. Alternatively, the isolation structure 206 may be a doped semiconductor region that is implanted with one or more types of dopants (e.g., p-type dopants, n-type dopants).

As another example, the transistor 104 and the variable resistor 110 may be electrically isolated from each other by an isolation structure 208. The transistor 106 and the variable resistor 112 may also be electrically isolated from each other by the isolation structure 208. The isolation structure 208 may be elongated in, and may extend in, the x-direction laterally between the transistor 104 and the variable resistor 110. The isolation structure 208 may also extend laterally between the transistor 106 and the variable resistor 112. The isolation structure 208 may include an STI structure that contains one or more dielectric materials such as silicon oxide (SiOₓ) and/or silicon nitride (SiₓN_{y}), among other examples. Alternatively, the isolation structure 208 may be a doped semiconductor region that is implanted with one or more types of dopants (e.g., p-type dopants, n-type dopants).

As further shown in FIG. 2A, the transistor 104 includes a gate structure 210 corresponding to the gate of the transistor 104. The transistor 104 further includes source/drain regions 212a and 212b (corresponding to the source/drains of the transistor 104) laterally adjacent to opposing sides of the gate structure 210 in the x-direction. The gate structure 210 and the source/drain regions 212a and 212b may extend in the y-direction and may be arranged in the x-direction in the circuit structure 200. The gate structure 210 may be spaced apart from the source/drain regions 212a and 212b in the x-direction, where the gate structure 210 may be located above the active region 202a and the source/drain regions 212a and 212b may be located adjacent to opposing sides of the active region 202a.

In some implementations, the gate structure 210 is a polysilicon gate structure. In some implementations, the gate structure 210 is a metal gate structure that contains one or more metal materials such as titanium (Ti), tungsten (W) and/or cobalt (Co), among other examples. In some implementations, the gate structure 210 includes a metal nitride such as titanium nitride (Ti₁₋ₓNₓ), among other examples. In some implementations, the gate structure 210 contains a metal silicide such as titanium silicide (TiSi) and/or ruthenium silicide (RuSi), among other examples. In some implementations, the metal silicide is a complex compound such as titanium/aluminum copper/titanium/titanium nitride (Ti/AlCu/Ti/TiN), among other examples. In implementations in which the transistor 104 is a pGaN HEMT structure, the gate structure 210 may contain a semiconductor material such as gallium nitride (GaN), aluminum gallium nitride (AlGaN), and/or doped gallium nitride (GaN), among other examples. For example, the gate structure 210 may contain gallium nitride doped with one or more p-type dopants such as boron (B). In implementations in which the transistor 104 is an n-type HEMT structure, the gate structure 210 may contain a semiconductor material such as doped gallium arsenide (GaAs). For example, the gate structure 210 may contain gallium arsenide doped with one or more n-type dopants such as phosphorous (P) and/or arsenic (As). The doped semiconductor material of the gate structure 210 may have a crystalline structure that is epitaxially grown on the active region 202a.

In some implementations, one or more dielectric layers may be located between the gate structure 210 and the active region 202a. The dielectric layer(s) may be included as capping layers, as passivation layers, and/or for another purpose, and may include one or more dielectric materials, such as a silicon oxide (SiOₓ), a silicon nitride (SiₓN_{y}), a doped silicon oxide, and/or a high dielectric constant (high-k) dielectric material such as hafnium oxide (HfOₓ), among other examples.

The source/drain regions 212a and 212b may each function as ohmic contacts of the transistor 104. Thus, the source/drain regions 212a and 212b may each contain one or more metals, one or more metal alloys, and/or other low-resistance materials that enable the current to flow through the source/drain regions 212a and 212b with minimal resistance and without exhibiting rectifying behavior. Examples of such materials include gold (Au), titanium (Ti), platinum (Pt), silver (Ag), and/or nickel (Ni), among other examples. Additionally and/or alternatively, the source/drain regions 212a and 212b may each contain doped semiconductor materials such as doped gallium nitride (GaN) and/or doped gallium arsenide (GaAs), among other examples.

As further shown in FIG. 2A, the gate structure 210 of the transistor 104 and the source/drain region 212b of the transistor 104 may be electrically coupled by interconnect structures 214, interconnect structures 216, and a metallization structure 218. The interconnect structures 214 may be located above and/or on the source/drain region 212b such that the interconnect structures 214 are electrically coupled and/or physically coupled to the source/drain region 212b. The interconnect structures 216 may be located above and/or on the gate structure 210 such that the interconnect structures 216 are electrically coupled and/or physically coupled to the gate structure 210. The metallization structure 218 may be located above and/or on the interconnect structures 214 and 216 such that the metallization structure 218 is electrically coupled and/or physically coupled to the interconnect structures 214 and 216.

The interconnect structures 214 and 216 may each include via structures, pillars, columns, and/or another type of interconnects that are primarily elongated in a z-direction in the circuit structure 200. The interconnect structures 214 and 216 may each include one or more electrically conductive materials such as tungsten (W), cobalt (Co), ruthenium (Ru), molybdenum (Mo), titanium (Ti), aluminum (Al), copper (Cu), gold (Au), and/or a combination thereof, among other examples of electrically conductive materials.

The interconnect structures 214 may be spaced apart and distributed along the source/drain region 212b in the y-direction. The interconnect structures 216 may be spaced apart and distributed along the gate structure 210 in the y-direction.

The metallization structure 218 may include one or more metal lines or trenches that extend in one or more lateral directions, such as the x-direction and/or the y-direction. The metallization structure 218 may include a first metal line that extends across the interconnect structures 214 and along the source/drain region 212b in the y-direction, and may include a plurality of second metal lines that extend in the x-direction from the first metal line to interconnect structures 216 over the gate structure 210. The metallization structure 218 may include one or more electrically conductive materials such as tungsten (W), cobalt (Co), ruthenium (Ru), molybdenum (Mo), titanium (Ti), aluminum (Al), copper (Cu), gold (Au), and/or a combination thereof, among other examples of electrically conductive materials.

As further shown in FIG. 2A, the transistor 106 includes a gate structure 220 corresponding to the gate of the transistor 106. The transistor 106 further includes source/drain regions 222a and 222b (corresponding to the source/drains of the transistor 106) laterally adjacent to opposing sides of the gate structure 220 in the x-direction. The gate structure 220 and the source/drain regions 222a and 222b may extend in the y-direction and may be arranged in the x-direction in the circuit structure 200. The gate structure 220 may be spaced apart from the source/drain regions 222a and 222b in the x-direction, where the gate structure 220 may be located above the active region 202b and the source/drain regions 222a and 222b may be located adjacent to opposing sides of the active region 202b. The source/drain regions 212a and 222b may be electrically isolated by the isolation structure 206 located laterally between the source/drain regions 212a and 222b.

In some implementations, the gate structure 220 is a polysilicon gate structure. In some implementations, the gate structure 220 is a metal gate structure that contains one or more metal materials such as tungsten (W) and/or cobalt (Co), among other examples. In some implementations, the gate structure 220 includes a metal nitride such as titanium nitride (Ti₁₋ₓNₓ), among other examples. In some implementations, the gate structure 220 contains a metal silicide such as titanium silicide (TiSi) and/or ruthenium silicide (RuSi), among other examples. In some implementations, the metal silicide is a complex compound such as titanium/aluminum copper/titanium/titanium nitride (Ti/AlCu/Ti/TiN), among other examples. In implementations in which the transistor 106 is a pGaN HEMT structure, the gate structure 220 may contain a semiconductor material such as gallium nitride (GaN), aluminum gallium nitride (AlGaN), and/or doped gallium nitride (GaN), among other examples. For example, the gate structure 220 may contain gallium nitride doped with one or more p-type dopants such as boron (B). In implementations in which the transistor 106 is an n-type HEMT structure, the gate structure 220 may contain a semiconductor material such as doped gallium arsenide (GaAs). For example, the gate structure 220 may contain gallium arsenide doped with one or more n-type dopants such as phosphorous (P) and/or arsenic (As). The doped semiconductor material of the gate structure 220 may have a crystalline structure that is epitaxially grown on the active region 202b.

In some implementations, one or more dielectric layers (not shown) may be located between the gate structure 220 and the active region 202b. The dielectric layer(s) be included as capping layers, as passivation layers, and/or for another purpose, and may include one or more dielectric materials, such as a silicon oxide (SiOₓ), a silicon nitride (SiₓN_{y}), a doped silicon oxide, and/or a high-k dielectric material such as hafnium oxide (HfOₓ), among other examples.

The source/drain regions 222a and 222b may each function as ohmic contacts of the transistor 106. Thus, the source/drain regions 222a and 222b may each contain one or more metals, one or more metal alloys, and/or other low-resistance materials that enable the current to flow through the source/drain regions 222a and 222b with minimal resistance and without exhibiting rectifying behavior. Examples of such materials include gold (Au), titanium (Ti), platinum (Pt), silver (Ag), and/or nickel (Ni), among other examples. Additionally and/or alternatively, the source/drain regions 222a and 222b may each contain doped semiconductor materials such as doped gallium nitride (GaN) and/or doped gallium arsenide (GaAs), among other examples.

As further shown in FIG. 2A, the gate structure 210 of the transistor 104 and the gate structure 220 of the transistor 106 may be electrically coupled together. The gate structures 210 and 220 may be segments of a unified gate structure that are coupled together by a gate connector segment 224 of the unified gate structure. The gate connector segment 224 may extend in the x-direction between the gate structures 210 and 220. The gate connector segment 224 may be located over a portion of the circuit isolation structure 204 such that the gate connector segment 224 extends along ends of the source/drain regions 222a and 212a. The gate structures 210, 220 and the gate connector segment 224 may form a substantially U-shaped top view shape for the unified gate structure. Thus, the circuit 102 may be referred to as a U-shaped dynamic current mirror (UDCM).

The source/drain region 212a of the transistor 104 may be electrically coupled and/or physically coupled to interconnect structures 226 above the source/drain region 212a. The interconnect structures 226 may be spaced apart and arranged along the source/drain region 212a in the y-direction. The interconnect structures 226 may be electrically coupled and/or physically coupled to a metallization structure 228. The metallization structure 228 may include a first metal line that extends across the interconnect structures 226 and along the source/drain region 212a in the y-direction, and a second metal line that extends across and over the top of the gate structure 220 and the source/drain regions 222a and 222b of the transistor 106 in the x-direction.

The source/drain region 222a of the transistor 106 may be electrically coupled and/or physically coupled to interconnect structures 230 above the source/drain region 222a. The interconnect structures 230 may be spaced apart and arranged along the source/drain region 222a in the y-direction. The interconnect structures 230 may be electrically coupled and/or physically coupled to a metallization structure 232. The metallization structure 232 may include a metal line that extends across the interconnect structures 230 and along the source/drain region 222a in the y-direction.

The source/drain region 222b of the transistor 106 may be electrically coupled and/or physically coupled to an interconnect structure 234 above the source/drain region 222b. The interconnect structure 234 may electrically couple the source/drain region 222b of the transistor 106 to another region of the semiconductor device so that the output current (Iₒᵤₜ) from the circuit 102 may be provided to the other region of the semiconductor device.

The interconnect structures 226, 230, and 234 may each include via structures, pillars, columns, and/or another type of interconnects that are primarily elongated in a z-direction in the circuit structure 200. The interconnect structures 226, 230, and 234 may each include one or more electrically conductive materials such as tungsten (W), cobalt (Co), ruthenium (Ru), molybdenum (Mo), titanium (Ti), aluminum (Al), copper (Cu), gold (Au), and/or a combination thereof, among other examples of electrically conductive materials.

The metallization structures 228 and 232 may each include one or more metal lines or trenches that extend in one or more lateral directions, such as the x-direction and/or the y-direction. The metallization structures 228 and 232 may each include one or more electrically conductive materials such as tungsten (W), cobalt (Co), ruthenium (Ru), molybdenum (Mo), titanium (Ti), aluminum (Al), copper (Cu), gold (Au), and/or a combination thereof, among other examples of electrically conductive materials.

As further shown in FIG. 2A, the variable resistor 110 may include contacts 236 and 238 at opposing ends of the variable resistor 110 in the x-direction. The contact 236 may be an input terminal of the variable resistor 110 that receives an input voltage (Vᵢₙ) from a power supply through an interconnect structure 240 above the contact 236. The contact 238 may be an output terminal of the variable resistor 110 that provides a reference current (I_{ref}) to the metallization structure 218 through an interconnect structure 242. The reference current is provided from the metallization structure 218 to the source/drain region 212b of the transistor 104 through the interconnect structures 214, to the gate structure 210 of the transistor 104 through the interconnect structures 216, and to the gate structure 220 of the transistor 106 through the gate connector segment 224. Thus, the variable resistor 110 is electrically coupled to the source/drain region 212b of the transistor 104 through the interconnect structures 214, to the gate structure 210 of the transistor 104 through the interconnect structures 216, and to the gate structure 220 of the transistor 106 through the gate connector segment 224. A portion of a metal line of the metallization structure 218 extends across the isolation structure 208 over the top of the isolation structure 208 and contacts the interconnect structure 242 above the contact 238.

As further shown in FIG. 2A, the variable resistor 110 may include a semiconductor region 244, a semiconductor layer 246 over and/or on the semiconductor region 244, and a contact 248 over and/or on the semiconductor layer 246. The contact 248 may correspond to a bias terminal of the variable resistor 110, and enables a voltage bias to be applied to the variable resistor 110 to modify the resistivity of the semiconductor region 244 and/or of the semiconductor layer 246.

The semiconductor region 244 and the semiconductor layer 246 may each contain a semiconductor material. In some implementations, the semiconductor region 244 and the semiconductor layer 246 may each contain the same semiconductor material. In some implementations, the semiconductor region 244 and the semiconductor layer 246 may each contain different semiconductor materials. In some implementations, the variable resistor 110 is formed by HEMT-like processes that are used to form the transistors 104 and 106. In these implementations, the semiconductor region 244 may be formed from the same semiconductor layer as the active regions 202a and 202b, and may contain the same semiconductor material(s) as the active regions 202a and 202b, such as aluminum gallium nitride (AlGaN) and/or aluminum gallium arsenide (AlGaAs), among other examples. Additionally and/or alternatively, the semiconductor layer 246 may be grown in the same epitaxial deposition operation as the gate structures 210 and 220, and may contain the same semiconductor material(s) as the gate structures 210 and 220, such as p-doped gallium nitride (p-GaN) and/or n-doped gallium arsenide (n-GaAs), among other examples.

The semiconductor region 244 and the semiconductor layer 246 may each extend in the x-direction laterally between the contacts 236 and 238. In some implementations, the semiconductor region 244 and/or the semiconductor layer 246 has a substantially rectangular top view shape, as shown in the example in FIG. 2A. In some implementations, the semiconductor region 244 and/or the semiconductor layer 246 has another top view shape, such as a zig-zag top view shape, a serpentine shape, and/or another top view shape.

The contact 248 may include a contact plug, a via structure, and/or another type of contact structure. In some implementations, the contact 248 may be formed during the same set of operations as the interconnect structures 214, 216, 230 234, 240, and/or 242, and may be formed of similar electrically conductive materials.

As further shown in FIG. 2A, the variable resistor 112 may include contacts 250 and 252 at opposing ends of the variable resistor 112 in the x-direction. The contact 252 may be an input terminal of the variable resistor 112 that is electrically coupled to the source/drain region 222a of the transistor 106. The contact 250 may be electrically coupled to the source/drain region 222a of the transistor 106 through an interconnect structure 254 above the contact 250, and through the metallization structure 232. A portion of the metallization structure 232 may extend across and over the top of the isolation structure 208, and may be coupled to the interconnect structure 254.

The contact 252 may be an output terminal of the variable resistor 112 that is electrically coupled to the electrical ground 108 of the circuit 102. The contact 252 may also be electrically coupled to the source/drain region 212a of the transistor 104 through an interconnect structure 256 and the metallization structure 228 so that the transistor 104 is electrically coupled to the electrical ground 108. A portion of the metallization structure 228 may extend across and over the top of the isolation structure 208, and may be coupled to the interconnect structure 256.

As further shown in FIG. 2A, the variable resistor 112 may include a semiconductor region 258, a semiconductor layer 260 over and/or on the semiconductor region 258, and a contact 262 over and/or on the semiconductor layer 260. The contact 262 may correspond to a bias terminal of the variable resistor 112, and enables a voltage bias to be applied to the variable resistor 112 to modify the resistivity of the semiconductor region 258 and/or of the semiconductor layer 260.

The semiconductor region 258 and the semiconductor layer 260 may each contain a semiconductor material. In some implementations, the semiconductor region 258 and the semiconductor layer 260 may each contain the same semiconductor material. In some implementations, the semiconductor region 258 and the semiconductor layer 260 may each contain different semiconductor materials. In some implementations, the variable resistor 112 is formed by HEMT-like processes that are used to form the transistors 104 and 106. In these implementations, the semiconductor region 258 may be formed from the same semiconductor layer as the active regions 202a and 202b, and may contain the same semiconductor material(s) as the active regions 202a and 202b such as aluminum gallium nitride (AlGaN) and/or aluminum gallium arsenide (AlGaAs), among other examples. Additionally and/or alternatively, the semiconductor layer 260 may be grown in the same epitaxial deposition operation as the gate structures 210 and 220, and may contain the same semiconductor material(s) as the gate structures 210 and 220, such as p-doped gallium nitride (p-GaN) and/or n-doped gallium arsenide (n-GaAs), among other examples.

The semiconductor region 258 and the semiconductor layer 260 may each extend in the x-direction laterally between the contacts 250 and 252. In some implementations, the semiconductor region 258 and/or the semiconductor layer 260 has a substantially rectangular top view shape, as shown in the example in FIG. 2A. In some implementations, the semiconductor region 258 and/or the semiconductor layer 260 has another top view shape, such as a zig-zag top view shape, a serpentine shape, and/or another top view shape.

The contact 262 may include a contact plug, a via structure, and/or another type of contact structure. In some implementations, the contact 248 may be formed during the same set of operations as the interconnect structures 214, 216, 230 234, 240, 242, 254, and/or 256, and may be formed of similar electrically conductive materials.

FIG. 2B illustrates a cross-section view of the circuit structure 200 along the line A-A′ in FIG. 2A, which is along the variable resistors 110 and 112 in the x-direction. As shown in FIG. 2B, the circuit structure 200 may be included above a substrate layer 264. The substrate layer 264 may include a layer of semiconductor material such as silicon (Si). In some implementations, the substrate layer 264 includes a layer of silicon carbide (SiC), a layer of crystalline aluminum oxide (e.g., sapphire), and/or another suitable substrate layer.

In some implementations, the substrate layer 264 corresponds to a portion of a semiconductor wafer (e.g., a silicon wafer) on which the circuit structure 200 is formed. A semiconductor layer 266 may be included above and/or on the substrate layer 264. The semiconductor layer 266 may include a layer of crystalline gallium nitride (GaN) that was epitaxially grown on the substrate layer 264.

As further shown in FIG. 2B, a two-dimensional electron gas (2DEG) layer 268 may be included under the variable resistor 110 in the semiconductor layer 266, and a 2DEG layer 270 may be included under the variable resistor 112 in the semiconductor layer 266. The 2DEG layer 268 and 270 each include a highly mobile electron layer formed at the interface of two different semiconductor materials. For example, the 2DEG layer 268 is formed at the interface between the semiconductor layer 266 and the semiconductor region 244. As another example, the 2DEG layer 270 is formed at the interface between the semiconductor layer 266 and the semiconductor region 258. The 2DEG layers 268 and 270 enable a very high electron mobility to be achieved for HEMTs, which gives the variable resistors 110 and 112 an HEMT-like structure.

In some implementations, the semiconductor layer 266, the semiconductor region 244, and/or the semiconductor region 258 may include a combination of semiconductor materials, such as AlGaN/AiN/GaN, AlGaN/GaN, AlGaN/GaN/InGaN/GaN, AlGaAs/GaAs, AlGaAs/InGaAs, InAlGaN/GaN, InAIN/GaN, InAIN/AlN/GaN, InAlAs/InGaAs, InAs/AlSb, InGaAs/InAlAs, InGaP/GaAs, InGaAs/GaAs, CdTe/PbTe, AlN/GaN, and/or AlInN/GaN, among other examples.

As further shown in FIG. 2B, an isolation layer 272 may be included over the circuit structure 200. The isolation layer 272 may provide electrical isolation and passivation for the circuit structure 200. The isolation layer 272 may include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an isolation layer 272 includes an extreme low dielectric constant (ELK) dielectric material having a dielectric constant that is less than approximately 2.5. Examples of ELK dielectric materials include carbon doped silicon oxide (C-SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples.

As further shown in FIG. 2B, the semiconductor layer 246 of the variable resistor 110 and/or the semiconductor layer 260 of the variable resistor 112 may have one or more dimensions. An example dimension D1 may correspond to a length of the semiconductor layer 246 of the variable resistor 110 and/or a length of the semiconductor layer 260 of the variable resistor 112 in the x-direction. In some implementations, the dimension D1 is included in a range of approximately 0.05 microns to approximately 1000 microns to provide sufficient control over the resistivity of the variable resistor 110 and/or of the variable resistor 112 while enabling a sufficiently small size to be achieved for the circuit structure 200. However, other values and ranges are within the scope of the present disclosure.

Another example dimension D2 may correspond to a thickness of the semiconductor layer 246 of the variable resistor 110 and/or a thickness of the semiconductor layer 260 of the variable resistor 112 in the z-direction. In some implementations, the dimension D2 is included in a range of approximately 0.005 microns to approximately 0.5 microns to provide sufficient control over the depletion of the 2DEG layer 268 and/or of the 2DEG layer 270 while enabling a relatively low current leakage to be achieved for the variable resistor 110 and/or for the variable resistor 112. However, other values and ranges are within the scope of the present disclosure.

Another example dimension D3 may correspond to a distance between an edge of the semiconductor layer 246 and a contact 236 and/or 238 of the variable resistor 110, and/or a distance between an edge of the semiconductor layer 260 and a contact 250 and/or 252 of the variable resistor 112 in the x-direction. In some implementations, the dimension D3 is included in a range of approximately 0.1 microns to approximately 500 microns to minimize the likelihood of punch through current in the variable resistor 110 and/or in the variable resistor 112 while enabling a sufficiently small size to be achieved for the circuit structure 200. However, other values and ranges are within the scope of the present disclosure.

In some implementations, the semiconductor layer 246 and/or the semiconductor layer 260 has a dopant concentration that is greater than approximately 1×10⁻¹⁹ atoms per cubic centimeter to provide sufficient depletion control while achieving a low likelihood of lattice defects. However, other values and ranges are within the scope of the present disclosure.

FIG. 2C illustrates a cross-section view of the circuit structure 200 along the line B-B′ in FIG. 2A, which is alongside the variable resistors 110 and 112 in the x-direction. As shown in FIG. 2C, the isolation layer 272 may be directly over the semiconductor regions 244 and 258. Moreover, the 2DEG layer 268 may span across the contacts 236 and 238 of the variable resistor 110 in the x-direction. The 2DEG layer 270 may span across the contacts 250 and 252 of the variable resistor 112 in the x-direction.

FIG. 2D illustrates a cross-section view of the circuit structure 200 along the line C-C′ in FIG. 2A, which is across the transistors 104 and 106 in the x-direction. As shown in FIG. 2D, the isolation layer 272 may be included over the transistors 104 and 106. The gate structures 210 and 220 may be respectively located above the active regions 202a and 202b, and may be covered by the isolation layer 272.

As further shown in FIG. 2D, the transistor 104 may include a 2DEG layer 274 under the active region 202 a, and the transistor 106 may include a 2DEG layer 276 under the active region 220 b. The 2DEG layer 274 may function as the channel layer of the transistor 104, and the 2DEG layer 276 may function as the channel layer of the transistor 106.

FIG. 2E illustrates a cross-section view of the circuit structure 200 along the line D-D′ in FIG. 2A, which is across the transistor 106 and the variable resistor 112 in the y-direction. As shown in FIG. 2E, the transistor 106 and the variable resistor 112 are laterally adjacent in the y-direction. Moreover, the transistor 106 and the variable resistor 112 are electrically isolated by the isolation structure 208 that is located laterally between the transistor 106 and the variable resistor 112 in the y-direction.

FIG. 2F illustrates a cross-section view of the circuit structure 200 along the line E-E′ in FIG. 2A, which is across the transistor structure 106 and the variable resistor 112 in the y-direction. As shown in FIG. 2F, the source/drain region 222a of the transistor 106 and the contact 250 of the variable resistor 112 are laterally adjacent in the y-direction. Moreover, the source/drain region 222a of the transistor 106 and the contact 250 of the variable resistor 112 are electrically isolated by the isolation structure 208 that is located laterally between the source/drain region 222a of the transistor 106 and the contact 250 of the variable resistor 112 in the y-direction.

FIG. 2G illustrates a cross-section view of the circuit structure 200 along the line F-F′ in FIG. 2A, which is across the transistor structure 104 and the variable resistor 110 in the y-direction. As shown in FIG. 2G, the source/drain region 212b of the transistor 104 and the contact 238 of the variable resistor 110 are laterally adjacent in the y-direction. Moreover, the source/drain region 212b of the transistor 104 and the contact 238 of the variable resistor 110 are electrically isolated by the isolation structure 208 that is located laterally between the source/drain region 212b of the transistor 104 and the contact 238 of the variable resistor 110 in the y-direction.

As indicated above, FIGS. 2A-2G are provided as an example. Other examples may differ from what is described with regard to FIGS. 2A-2G.

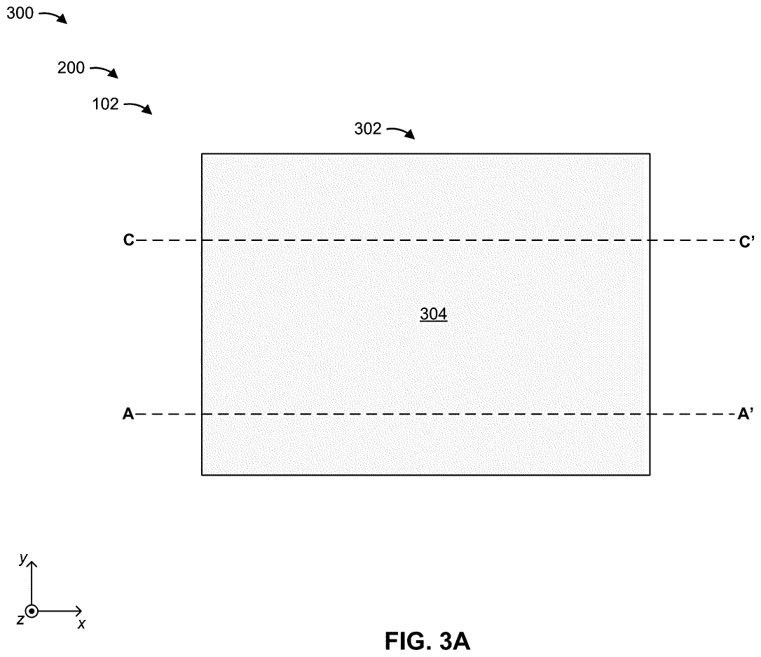

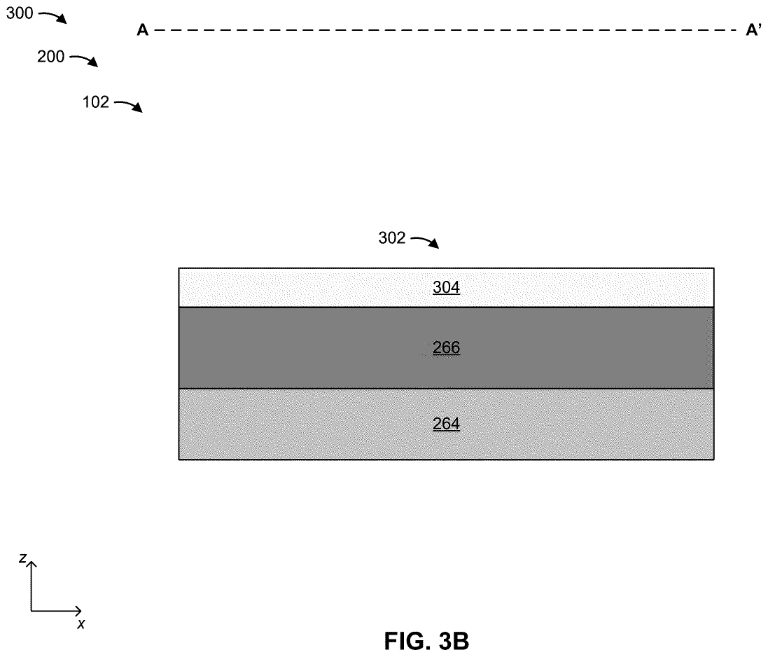

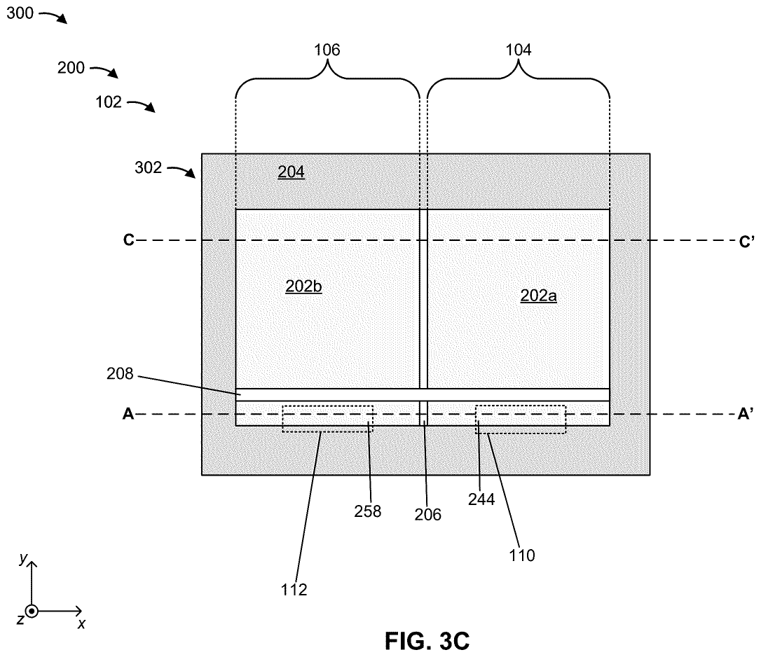

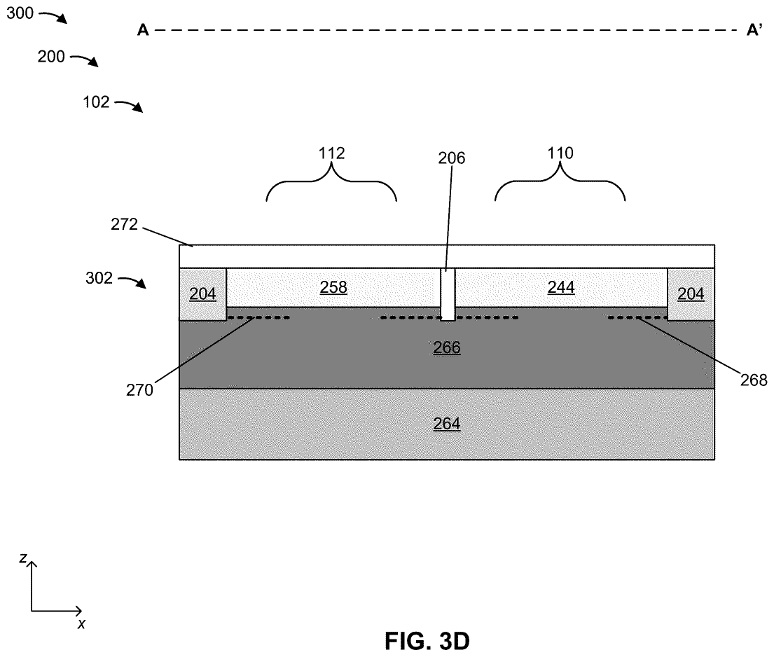

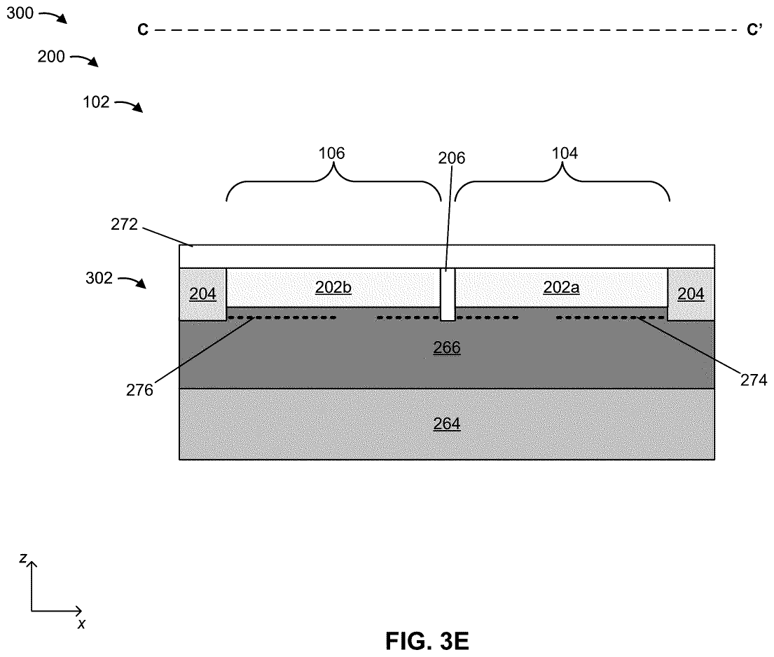

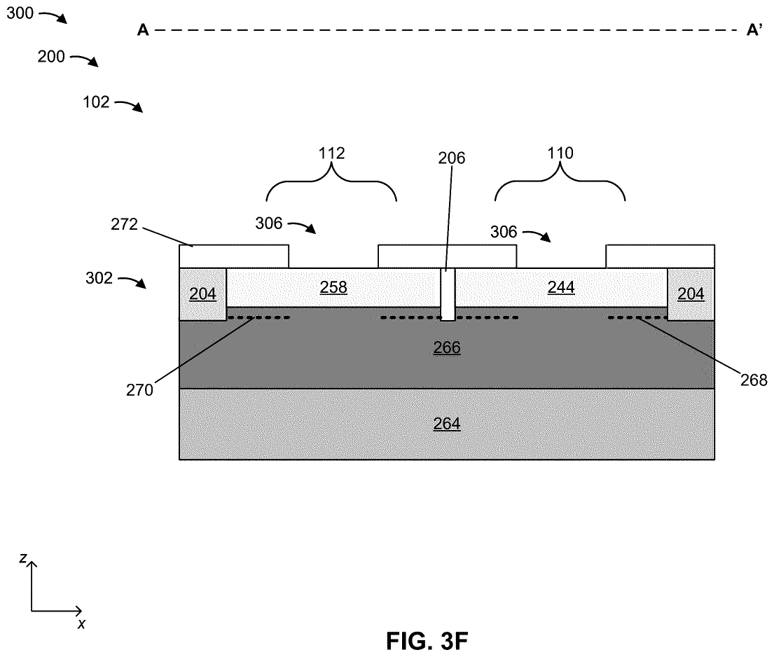

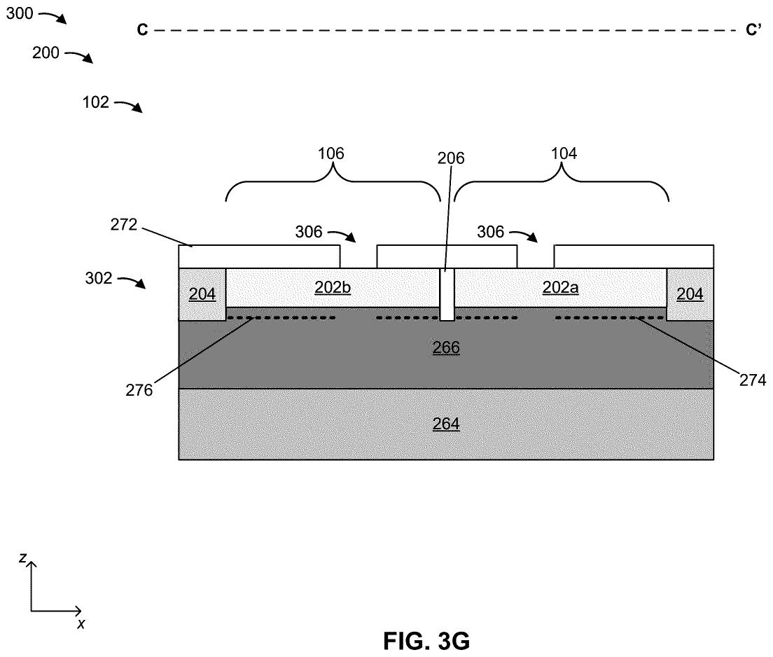

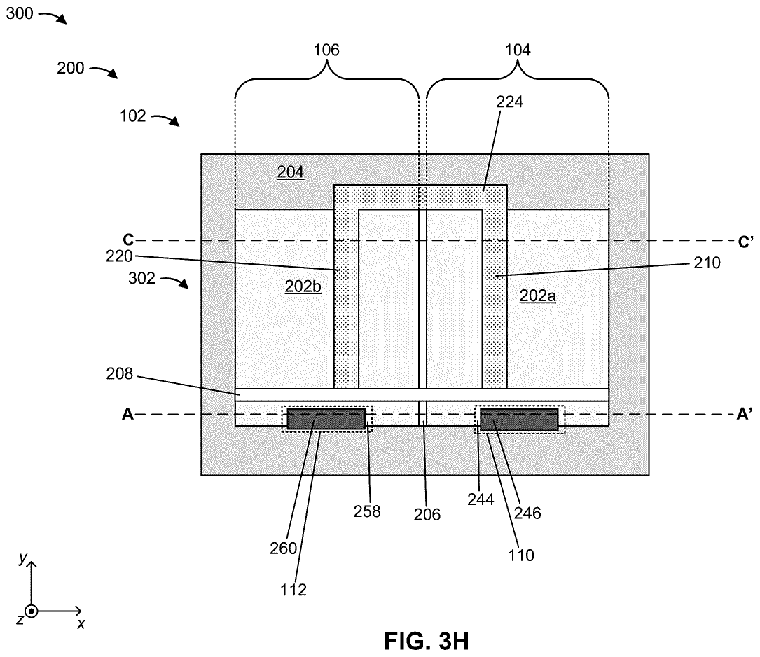

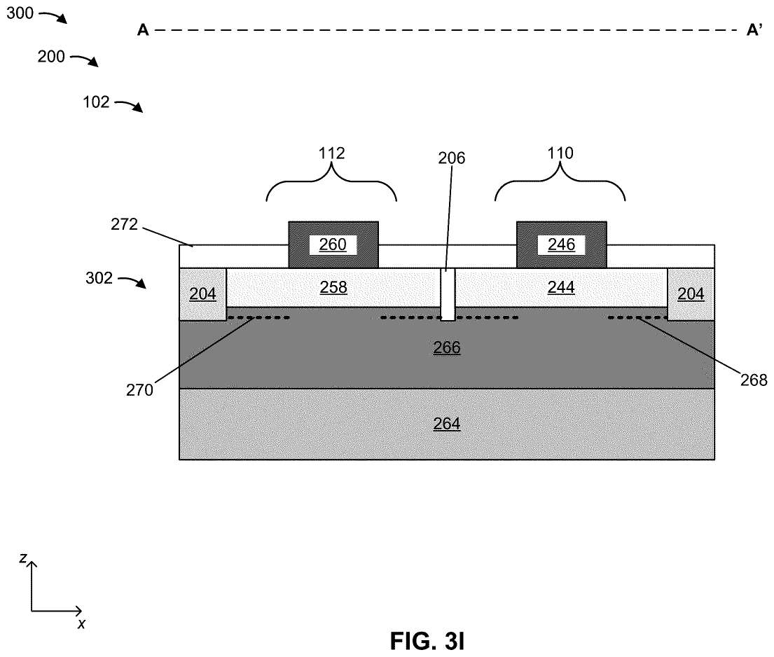

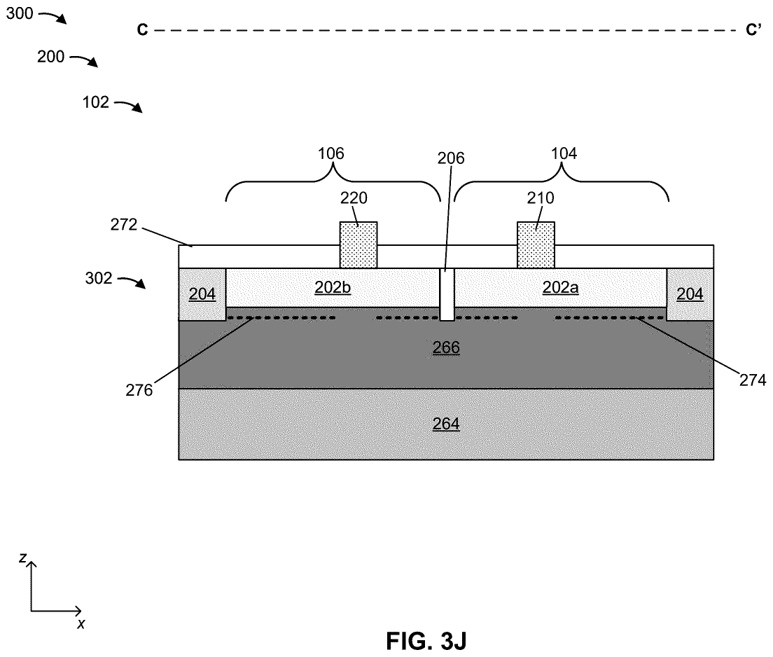

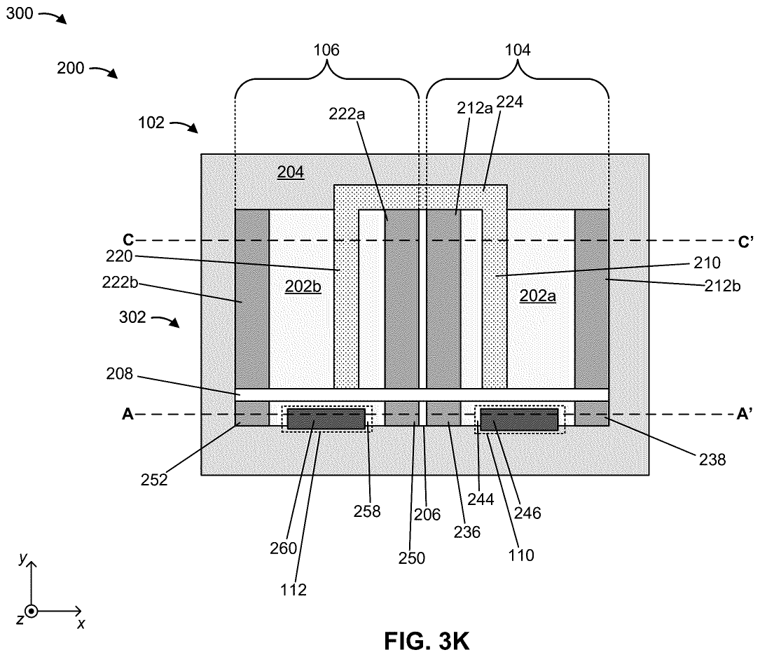

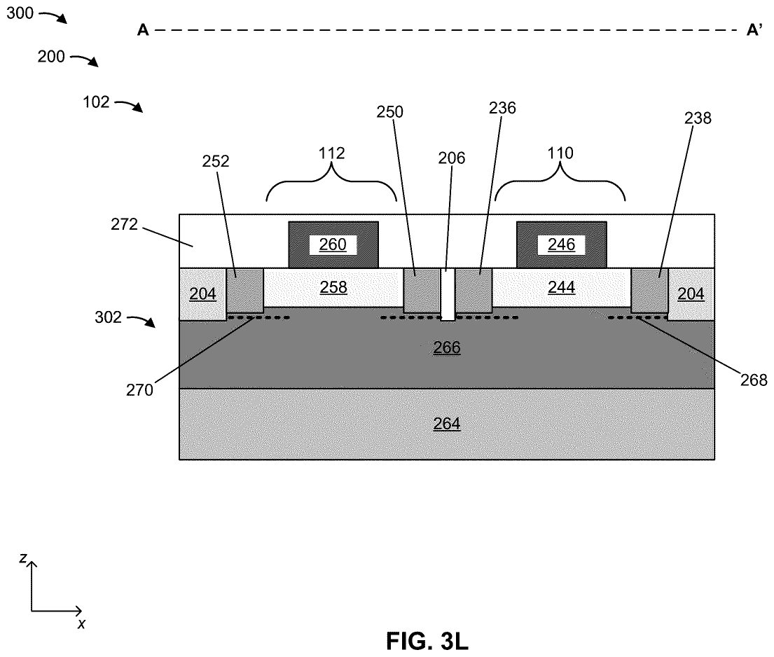

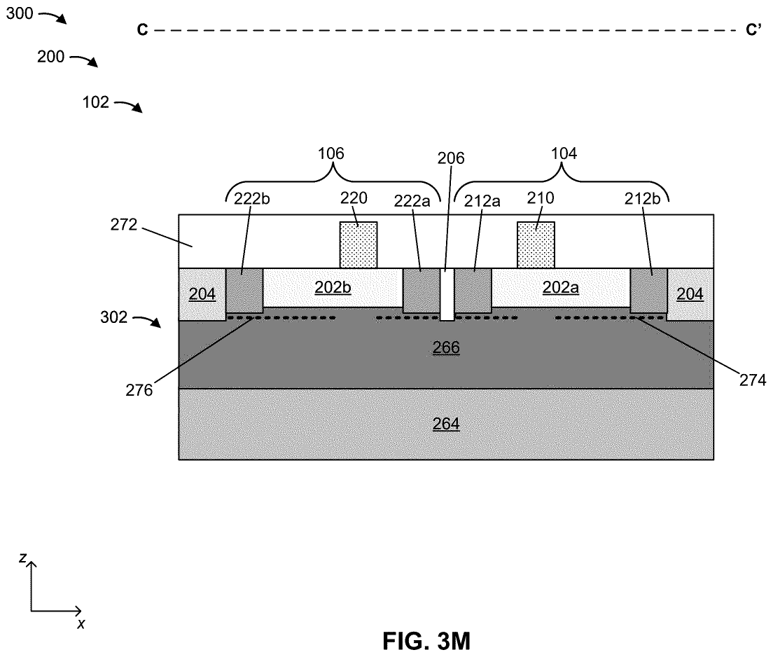

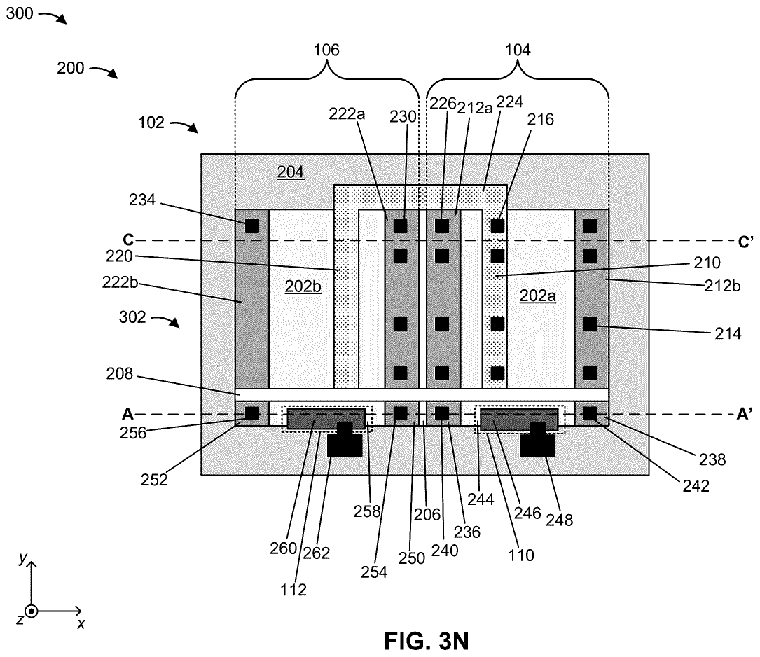

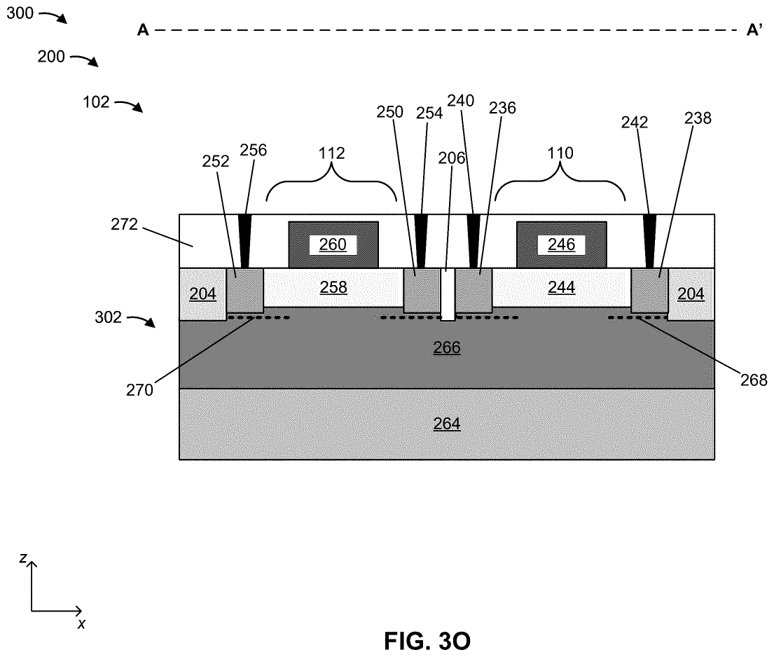

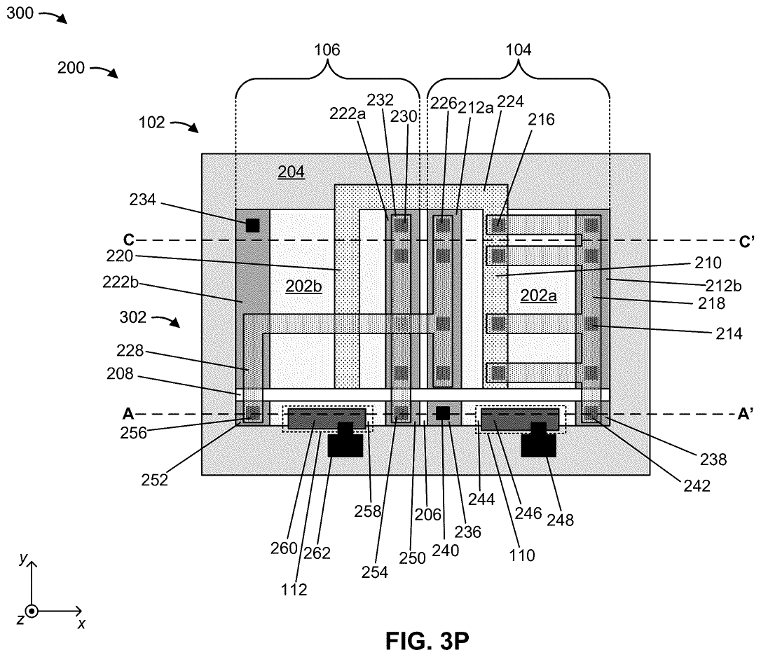

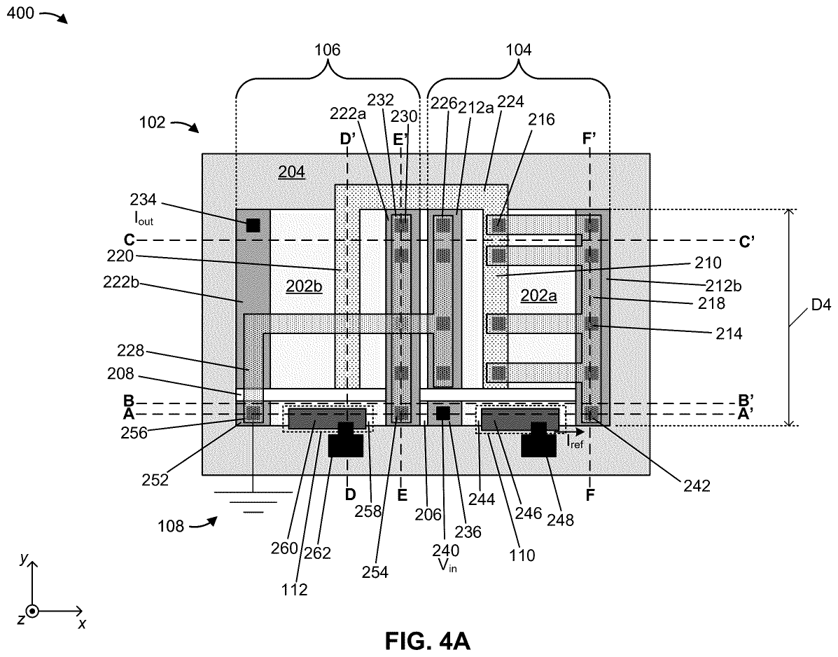

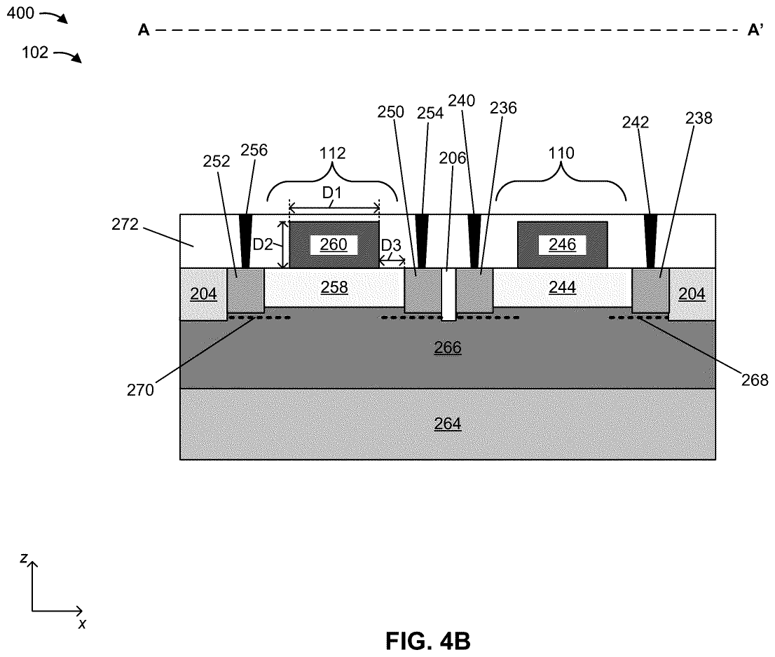

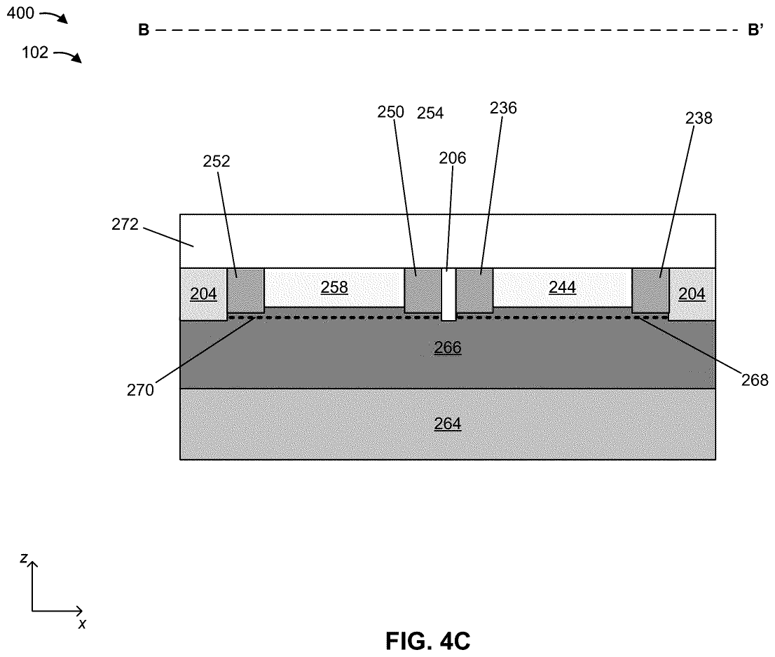

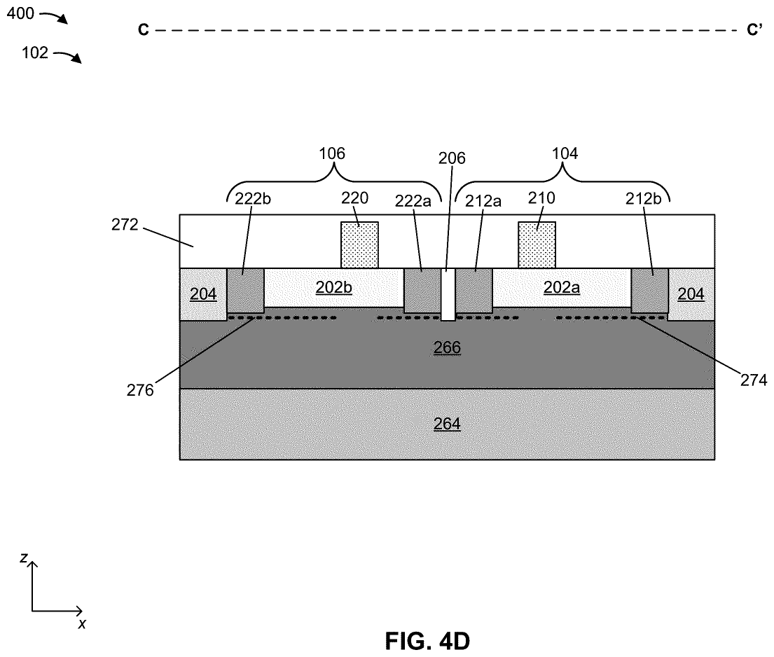

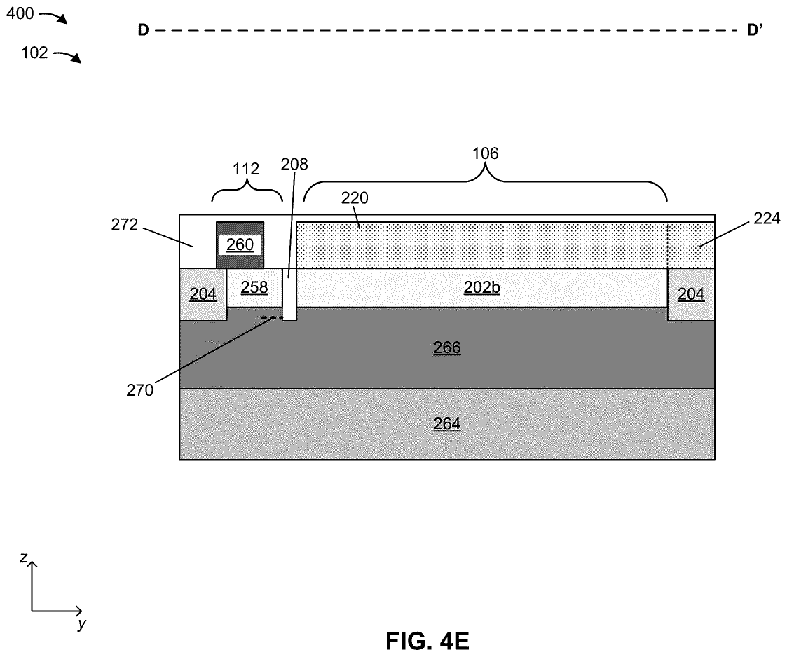

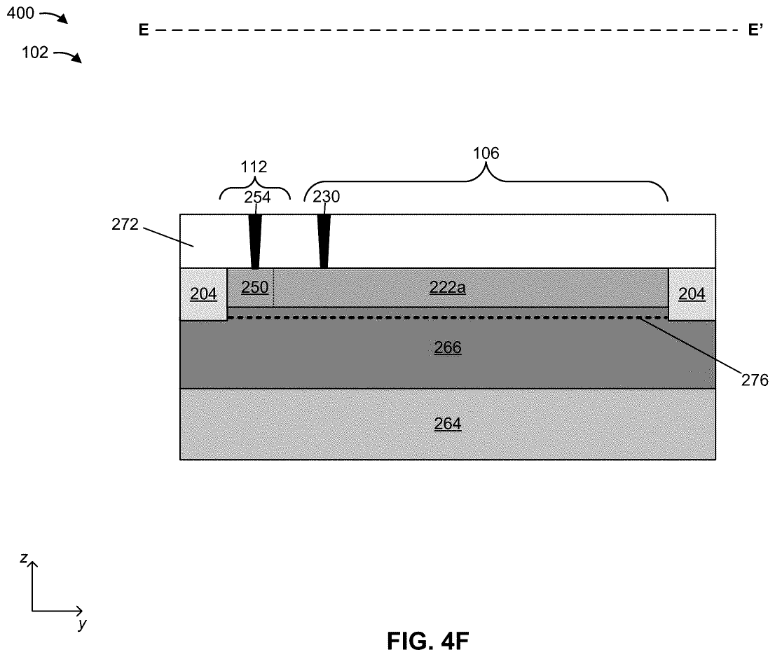

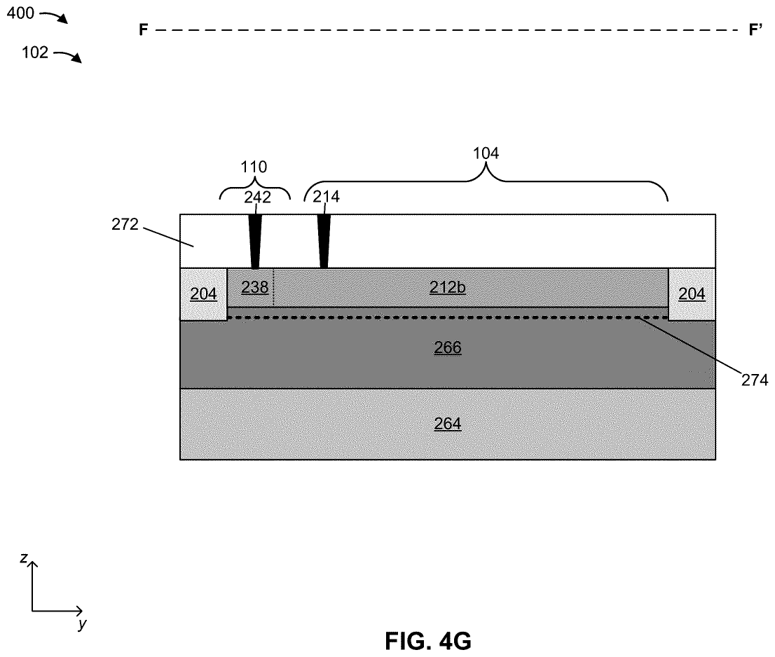

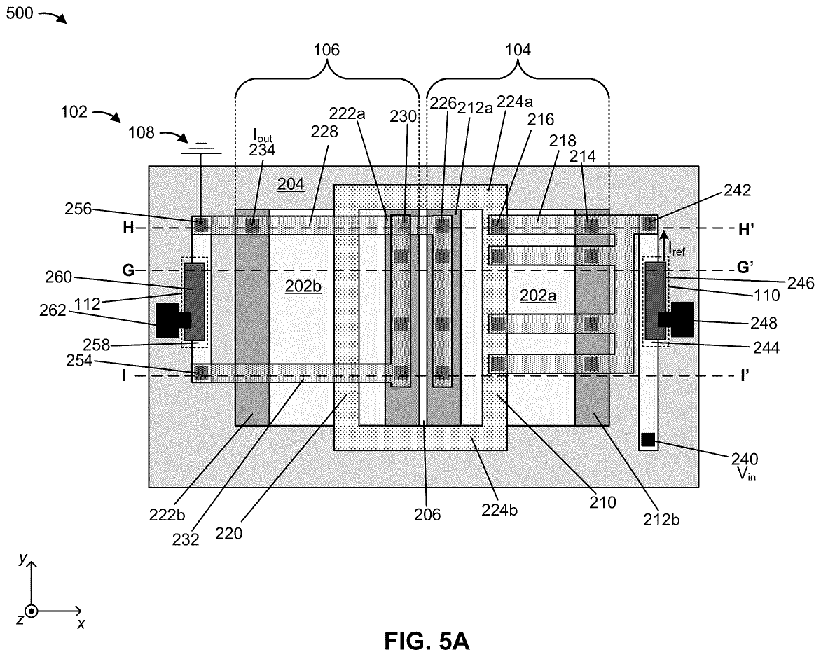

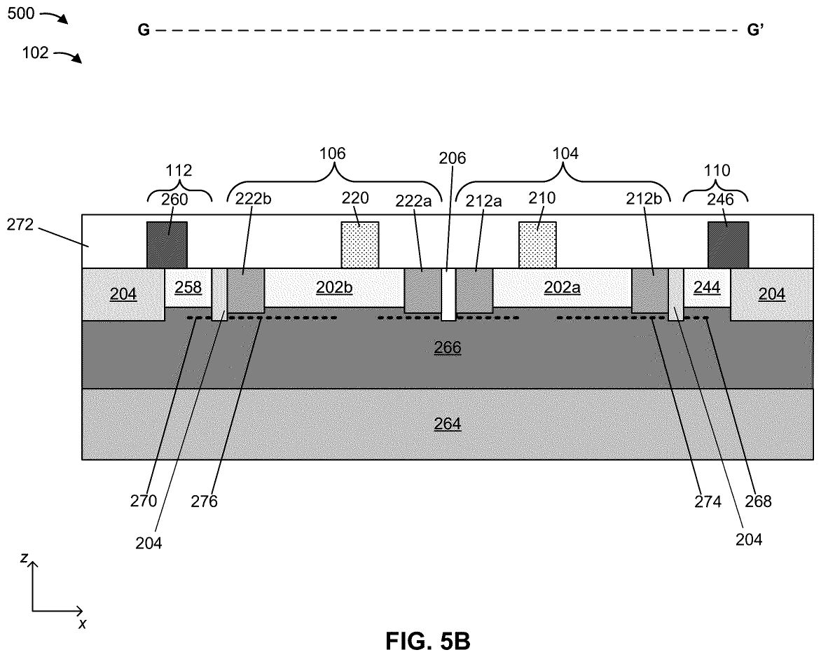

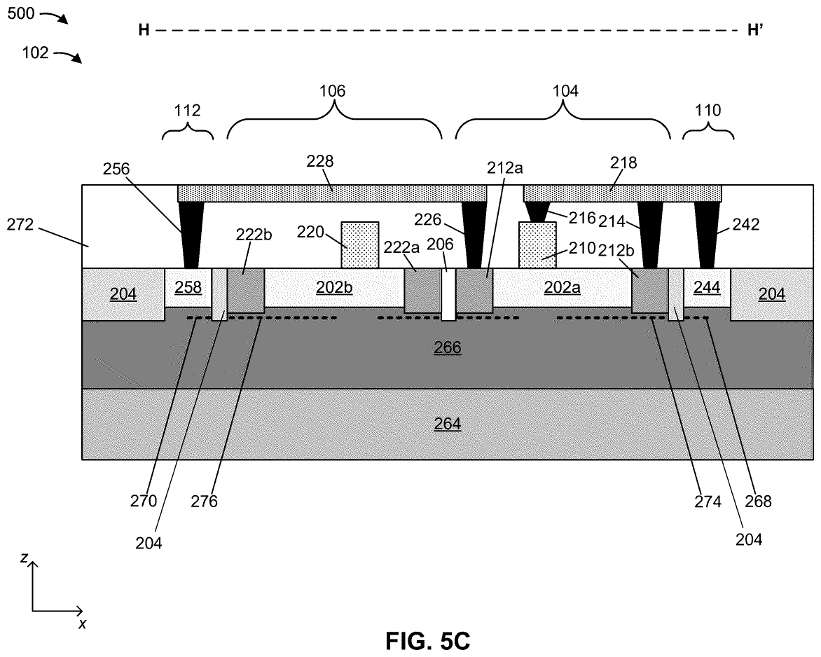

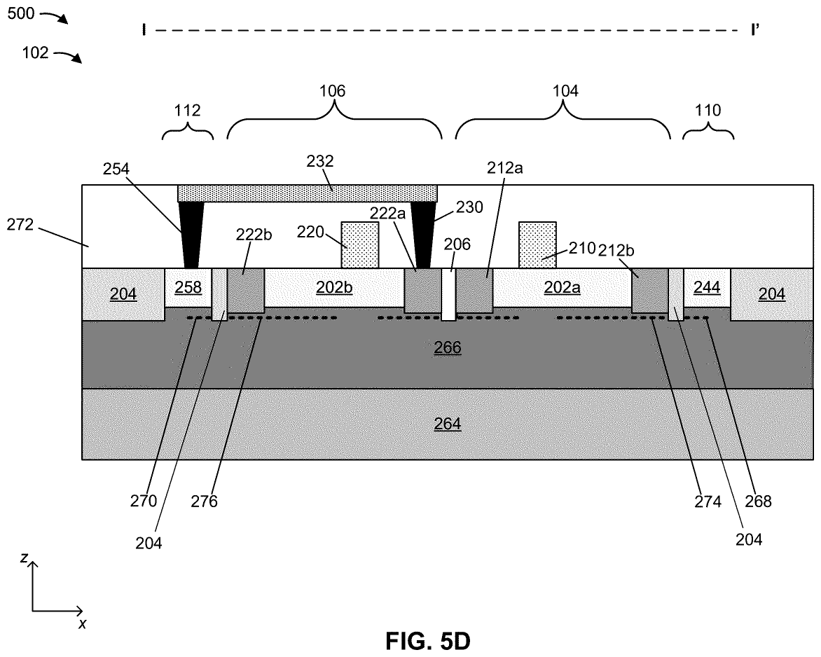

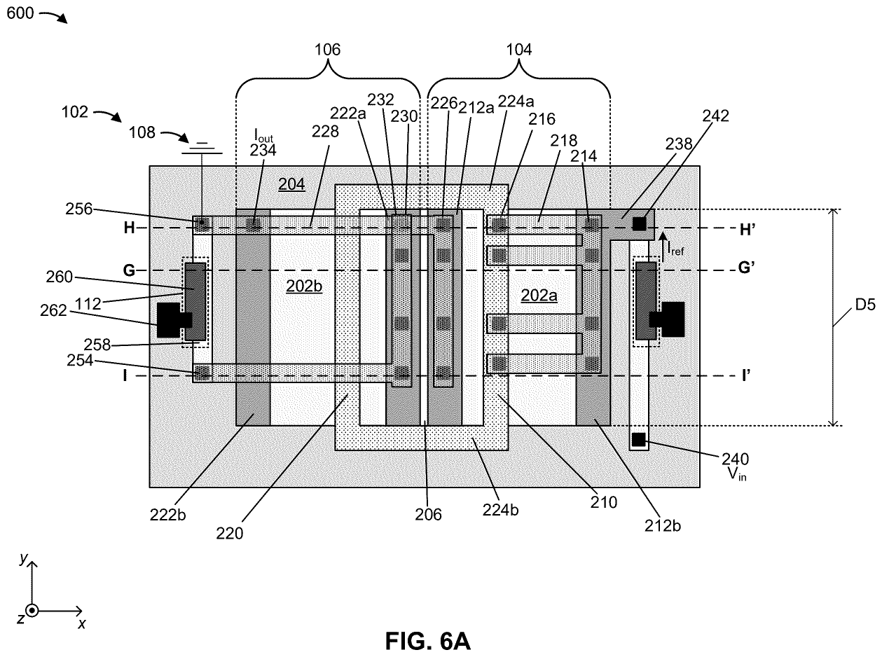

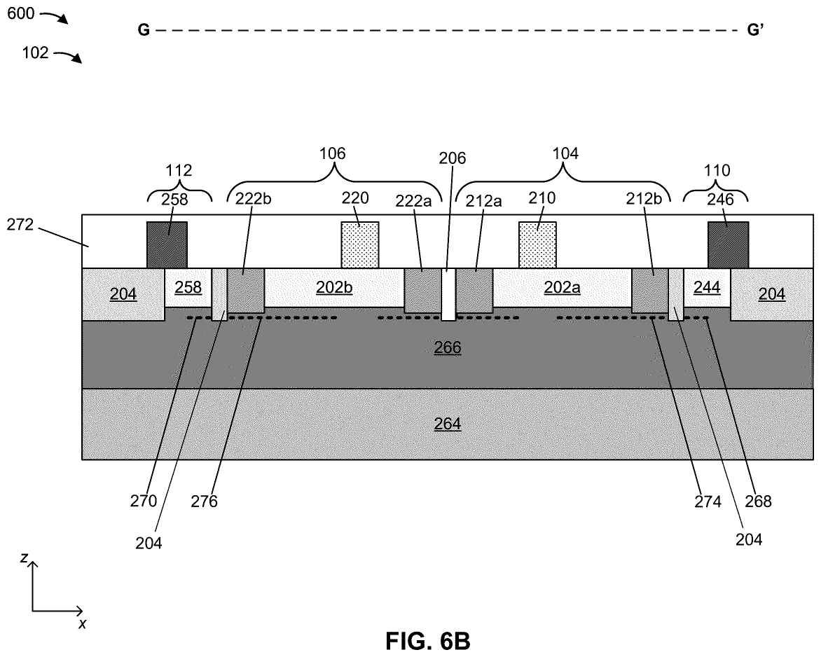

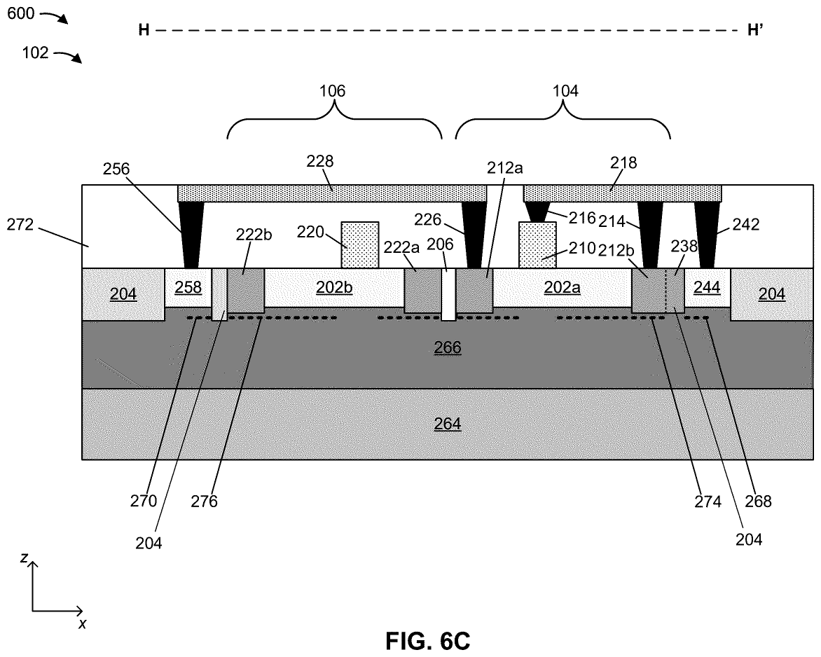

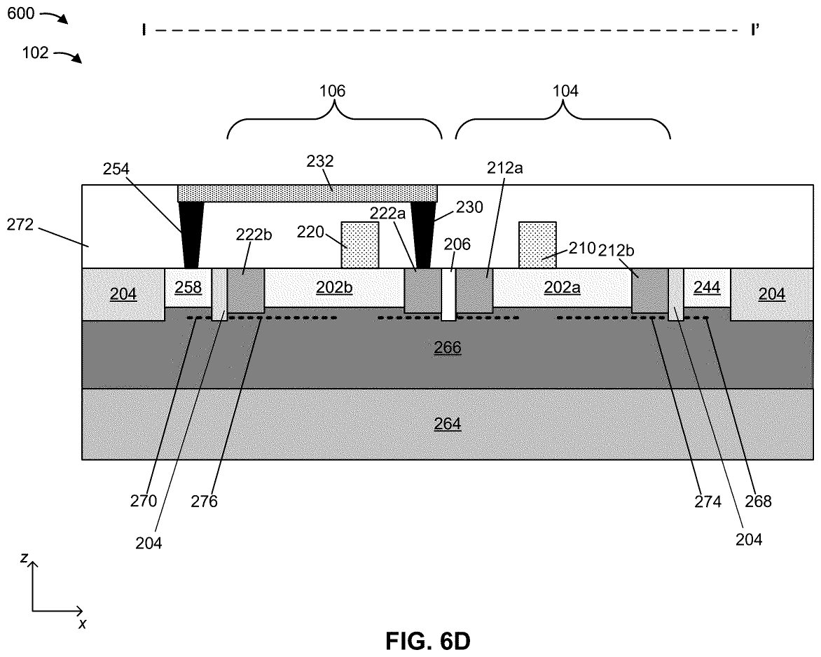

FIGS. 3A-3P are diagrams of an example implementation 300 of forming a circuit structure described herein. For example, the example implementation 300 may include an example of forming the circuit structure 200 illustrated in FIGS. 2A-2G. In some implementations, one or more operations performed in connection with FIGS. 3A-3P may be performed to form another circuit structure described herein, such as a circuit structure 400 illustrated in FIGS. 4A-4G, a circuit structure 500 illustrated in FIGS. 5A-5D, and/or a circuit structure 600 illustrated in FIGS. 6A-6D, among other examples. In some implementations, one or more operations described in connection with FIGS. 3A-3P may be performed using one or more semiconductor processing tools, such as an exposure tool, a developer tool, an etch tool, a deposition tool, a planarization tool, and/or an ion implantation tool, among other examples.

As shown in FIGS. 3A and 3B, a semiconductor device 302 may be provided. The semiconductor device 302 may be provided in the form of a semiconductor wafer, a semiconductor die, and/or another type of semiconductor work piece. The semiconductor device 302 may include the substrate layer 264, the semiconductor layer 266, and a semiconductor layer 304. In some implementations, the substrate layer 264 is provided, and the semiconductor layer 266 and the semiconductor layer 304 may be formed on the substrate layer 264. In some implementations, the semiconductor layer 266 and the semiconductor layer 304 may be pre-formed on the substrate layer 264, and the stack of the substrate layer 264, the semiconductor layer 266, and the semiconductor layer 304 may be provided as the semiconductor device 302.

A deposition tool may be used to epitaxially grow the semiconductor layer 266 on the substrate layer 264. A deposition tool may be used to epitaxially grow the semiconductor layer 304 on the semiconductor layer 266. The semiconductor layer 266 and the semiconductor layer 304 may be formed of different semiconductor materials. For example, the semiconductor layer 266 may be formed of epitaxially-grown gallium nitride (GaN) (e.g., crystalline gallium nitride), and the semiconductor layer 304 may be formed of epitaxially-grown aluminum gallium nitride (AlGaN) (e.g., crystalline aluminum gallium nitride). Other combinations of semiconductor materials for the semiconductor layer 266 and the semiconductor layer 304 are within the scope of the present disclosure. Alternatively, the semiconductor layer 266 and the semiconductor layer 304 may be formed of the same semiconductor material.

As shown in FIG. 3C, various isolation structures may be formed in the semiconductor layer 304. For example, the semiconductor layer 304 may be etched based on a pattern in a patterning layer to form trenches in the semiconductor layer 304, and the trenches may be filled with dielectric material to form the circuit isolation structure 204, the isolation structure 206, and/or the isolation structure 208. The circuit isolation structure 204, the isolation structure 206, and/or the isolation structure 208 may define the active region 202a of the transistor 104, the active region 202b of the transistor 106, the semiconductor region 244 of the variable resistor 110, and/or the semiconductor region 258 of the variable resistor 112.

A deposition tool may be used to form the patterning layer on the semiconductor layer 304 (e.g., using a spin-coating technique and/or another suitable deposition technique). An exposure tool may be used to expose the patterning layer to a radiation source to pattern the patterning layer. A developer tool may be used to develop and remove portions of the patterning layer to expose the pattern. An etch tool may be used to etch the semiconductor layer 304 based on the pattern to form the trenches. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the patterning layer (e.g., using a chemical stripper, plasma ashing, and/or another technique). In some implementations, a hard mask layer is used as an alternative technique for etching the semiconductor layer 304 based on a pattern.

A deposition tool may be used to deposit the dielectric material of the circuit isolation structure 204, the isolation structure 206, and/or the isolation structure 208 using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to perform a planarization operation (e.g., a chemical-mechanical planarization (CMP) operation) to planarize the circuit isolation structure 204, the isolation structure 206, and/or the isolation structure 208 after the circuit isolation structure 204, the isolation structure 206, and/or the isolation structure 208 is deposited.

Additionally and/or alternatively, a pattern may be formed in an implant mask, and an ion implantation tool may be used to implant dopants in the semiconductor layer 304 to form the circuit isolation structure 204, the isolation structure 206, and/or the isolation structure 208.

As shown in FIGS. 3D and 3E, the isolation layer 272 may be deposited over the semiconductor device 302. A deposition tool may be used to deposit the isolation layer 272 using a PVD technique, an ALD technique, a CVD technique, an oxidation technique, and/or another suitable deposition technique. The isolation layer 272 may be deposited in one or more deposition operations. In some implementations, a planarization tool may be used to perform a planarization operation (e.g., a CMP operation) to planarize the isolation layer 272 after the isolation layer 272 is deposited.

As further shown in FIG. 3D, formation of the circuit isolation structure 204, the isolation structure 206, and/or the isolation structure 208 defines the 2DEG layer 268 of the variable resistor 110 and the 2DEG layer 270 of the variable resistor 112. The 2DEG layers 268 and 270 are formed at the interface between the semiconductor layer 266 and the semiconductor layer 304.

As further shown in FIG. 3E, formation of the circuit isolation structure 204, the isolation structure 206, and/or the isolation structure 208 defines the 2DEG layer 274 of the transistor 106 and the 2DEG layer 276 of the transistor 104. The 2DEG layers 274 and 276 are formed at the interface between the semiconductor layer 266 and the semiconductor layer 304.

As shown in FIGS. 3F and 3G, a pattern 306 may be formed in the isolation layer 272. In some implementations, a pattern in a photoresist layer is used to etch the isolation layer 272 to form the pattern 306. In these implementations, a deposition tool may be used to form the photoresist layer on the isolation layer 272 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the isolation layer 272 based on the pattern to form the pattern 306. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the isolation layer 272 based on a pattern.

As shown in FIG. 3F, the pattern 306 may include an opening through the isolation layer 272 above a portion of the semiconductor region 244 of the variable resistor 110, and/or an opening through the isolation layer 272 above a portion of the semiconductor region 258 of the variable resistor 112.

As shown in FIG. 3G, the pattern 306 may include an opening through the isolation layer 272 above a portion of the active region 202a of the transistor 104, and/or an opening through the isolation layer 272 above a portion of the active region 202b of the transistor 106.

As shown in FIGS. 3H-3J, the gate structure 210, the gate structure 220, the gate connector segment 224, the semiconductor layer 246, and the semiconductor layer 260 may be formed in the openings of the isolation layer 272 based on the pattern 306. In some implementations, the material of the gate structure 210, the gate structure 220, the gate connector segment 224, the semiconductor layer 246, and the semiconductor layer 260 is deposited in a same deposition operation. For example, a deposition tool may be used to epitaxially grow the doped semiconductor material of the gate structure 210, the gate structure 220, the gate connector segment 224, the semiconductor layer 246, and the semiconductor layer 260 in the openings through the isolation layer 272. As another example, a deposition tool may be used to deposit the material of the gate structure 210, the gate structure 220, the gate connector segment 224, the semiconductor layer 246, and the semiconductor layer 260 using a CVD technique and/or another suitable deposition technique.

In some implementations, two or more of the gate structure 210, the gate structure 220, the gate connector segment 224, the semiconductor layer 246, and/or the semiconductor layer 260 are deposited in separate deposition operations.

As shown in FIGS. 3H and 3I, the semiconductor layer 246 of the variable resistor 110 may be deposited over and/or on a portion of the semiconductor region 244. The semiconductor layer 260 of the variable resistor 112 may be deposited over and/or on a portion of the semiconductor region 258.

As shown in FIGS. 3H and 3J, the gate structure 210 of the transistor 104 may be deposited over and/or on a portion of the active region 202a. The gate structure 220 of the transistor 106 may be deposited over and/or on the active region 202b.

As shown in FIG. 3H, the gate connector segment 224 may be deposited over and/or on a portion of the circuit isolation structure 204.

As shown in FIGS. 3K-3M, the source/drain regions 212a and 212b of the transistor 104, the source/drain regions 222a and 222b of the transistor 106, the contacts 236 and 238 of the variable resistor 110, and the contacts 250 and 252 of the variable resistor 112 may be formed. The source/drain regions 212a and 212b may be formed on opposing sides of the active region 202a such that the source/drain regions 212a and 212b are located laterally adjacent to opposing sides of the gate structure 210 in the x-direction. The source/drain regions 222a and 222b may be formed on opposing sides of the active region 202b such that the source/drain regions 222a and 222b are located laterally adjacent to opposing sides of the gate structure 220 in the x-direction. The contacts 236 and 238 may be formed on opposing sides of the semiconductor region 244 of the variable resistor 110 in the x-direction. The contacts 250 and 252 may be formed on opposing sides of the semiconductor region 258 of the variable resistor 112 in the x-direction.

In some implementations, forming the source/drain regions 212a and 212b may include using an ion implantation tool to implant dopants in the active region 202a to form the source/drain regions 212a and 212b. In some implementations, forming the source/drain regions 212a and 212b includes etching the active region 202a to form trenches in the active region 202a, and depositing material of the source/drain regions 212a and 212b in the trenches.

In some implementations, forming the source/drain regions 222a and 222b may include using an ion implantation tool to implant dopants in the active region 202b to form the source/drain regions 222a and 222b. In some implementations, forming the source/drain regions 222a and 222b includes etching the active region 202b to form trenches in the active region 202b, and depositing material of the source/drain regions 222a and 222b in the trenches.

In some implementations, forming the contacts 236 and 238 may include using an ion implantation tool to implant dopants in the semiconductor region 244 to form the contacts 236 and 238. In some implementations, forming the contacts 236 and 238 includes etching the semiconductor region 244 to form recesses in the semiconductor region 244, and depositing material of the contacts 236 and 238 in the recesses.

In some implementations, forming the contacts 250 and 252 may include using an ion implantation tool to implant dopants in the semiconductor region 258 to form the contacts 250 and 252. In some implementations, forming the contacts 250 and 252 includes etching the semiconductor region 258 to form recesses in the semiconductor region 258, and depositing material of the contacts 250 and 252 in the recesses.

As shown in FIGS. 3N and 30, the interconnect structures 214 may be formed over and/or on the source/drain region 212b such that the interconnect structures 214 are electrically coupled and/or physically coupled to the source/drain region 212b. The interconnect structures 216 may be formed over and/or on the gate structure 210 such that the interconnect structures 216 are electrically coupled and/or physically coupled to the gate structure 210. The interconnect structures 226 may be formed over and/or on the source/drain region 212a such that the interconnect structures 226 are electrically coupled and/or physically coupled to the source/drain region 212a. The interconnect structures 230 may be formed over and/or on the source/drain region 222a such that the interconnect structures 230 are electrically coupled and/or physically coupled to the source/drain region 222a. The interconnect structure 234 may be formed over and/or on the source/drain region 222b such that the interconnect structure 234 is electrically coupled and/or physically coupled to the source/drain region 222b.

The interconnect structure 240 may be formed over and/or on the contact 236 such that the interconnect structure 240 is electrically coupled and/or physically coupled to the contact 236. The interconnect structure 242 may be formed over and/or on the contact 238 such that the interconnect structure 242 is electrically coupled and/or physically coupled to the contact 238. The interconnect structure 254 may be formed over and/or on the contact 250 such that the interconnect structure 254 is electrically coupled and/or physically coupled to the contact 250. The interconnect structure 256 may be formed over and/or on the contact 252 such that the interconnect structure 256 is electrically coupled and/or physically coupled to the contact 252.

The contact 248 may be formed over and/or on the semiconductor layer 246 of the variable resistor 110 such that the contact 248 is electrically coupled and/or physically coupled to the semiconductor layer 246. The contact 262 may be formed over and/or on the semiconductor layer 260 of the variable resistor 112 such that the contact 262 is electrically coupled and/or physically coupled to the semiconductor region 260.

To form the interconnect structures 214, 216, 226, 230, 234, 240, 242, 254, and/or 256, additional material (or additional layers) of the isolation layer 272 may be formed. Recesses (e.g., vias, openings) may be formed through the isolation layer 272, and electrically conductive material may be deposited in the recesses to form the interconnect structures 214, 216, 226, 230, 234, 240, 242, 254, and/or 256.

In some implementations, a pattern in a photoresist layer is used to etch the isolation layer 272 to form the recesses. In these implementations, a deposition tool may be used to form the photoresist layer on the isolation layer 272 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the isolation layer 272 based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the isolation layer 272 based on a pattern.

A deposition tool may be used to deposit the material of the interconnect structure 214, 216, 226, 230, 234, 240, 242, 254, and/or 256 using a CVD technique, a PVD technique, an ALD technique, an electroplating technique, and/or another suitable deposition technique. The interconnect structure 214, 216, 226, 230, 234, 240, 242, 254, and/or 256 may be deposited in one or more deposition operations. In some implementations, a seed layer is first deposited, and the interconnect structure 214, 216, 226, 230, 234, 240, 242, 254, and/or 256 is deposited on the seed layer. In some implementations, a planarization tool is used to perform a planarization operation (e.g., a CMP operation) to planarize the interconnect structure 214, 216, 226, 230, 234, 240, 242, 254, and/or 256 after the interconnect structure 214, 216, 226, 230, 234, 240, 242, 254, and/or 256 is deposited.

The contacts 248 and 262 may be formed in a similar manner as the interconnect structures 214, 216, 226, 230, 234, 240, 242, 254, and/or 256. In some implementations, the contacts 248 and 262 are formed as dual damascene structures that include a via and a trench. In these implementations, the via of the contact 248 may be formed over and/or on the semiconductor layer 246 of the variable resistor 110, and the trench of the contact 248 may be formed over and/or on the via, and may extend laterally outward over the circuit isolation structure 204. In these implementations, the via of the contact 262 may be formed over and/or on the semiconductor layer 260 of the variable resistor 112, and the trench of the contact 262 may be formed over and/or on the via, and may extend laterally outward over the circuit isolation structure 204.

As shown in FIG. 3P, the metallization structures 218, 228, and/or 232 may be formed. The metallization structure 218 may be formed such that the metallization structure 218 extends over the source/drain region 212b and over the interconnect structures 214. Moreover, the metallization structure 218 may be formed such that the metallization structure 218 extends across the isolation structure 208 and over the interconnect structure 242. Moreover, the metallization structure 218 may be formed such that the metallization structure 218 extends across the active region 202a and over the interconnect structures 216 that are coupled to the gate structure 210.

The metallization structure 228 may be formed such that the metallization structure 228 extends over the source/drain region 212a and over the interconnect structures 226. Moreover, the metallization structure 228 may be formed such that the metallization structure 228 extends across the isolation structure 206, across the source/drain region 222a, across the active region 202b, across the source/drain region 222b, across the isolation structure 208, and over the interconnect structure 256.

The metallization structure 232 may be formed such that the metallization structure 232 extends over the source/drain region 222a and over the interconnect structures 230. Moreover, the metallization structure 232 may be formed such that the metallization structure 232 extends across the isolation structure 208 and over the interconnect structure 254.

To form the metallization structure 218, 228, and/or 232, additional material (or additional layers) of the isolation layer 272 may be formed. Recesses may be formed through the isolation layer 272, and electrically conductive material may be deposited into the recesses to form the metallization structure 218, 228, and/or 232.

In some implementations, a pattern in a photoresist layer is used to etch the isolation layer 272 to form the recesses. In these implementations, a deposition tool may be used to form the photoresist layer on the isolation layer 272 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the isolation layer 272 based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the isolation layer 272 based on a pattern.

A deposition tool may be used to deposit the material of the metallization structure 218, 228, and/or 232 using a CVD technique, a PVD technique, an ALD technique, an electroplating technique, and/or another suitable deposition technique. The metallization structure 218, 228, and/or 232 may be deposited in one or more deposition operations. In some implementations, a seed layer is first deposited, and the metallization structure 218, 228, and/or 232 is deposited on the seed layer. In some implementations, a planarization tool is used to perform a planarization operation (e.g., a CMP operation) to planarize the metallization structure 218, 228, and/or 232 after the metallization structure 218, 228, and/or 232 is deposited.

As indicated above, FIGS. 3A-3P are provided as an example. Other examples may differ from what is described with regard to FIGS. 3A-3P.

FIGS. 4A-4G are diagrams of an example circuit structure 400 of the circuit 102 described herein. In particular, the circuit structure 400 is an example of a circuit structure implementation of the circuit 102 in which the circuit 102 is implemented in a semiconductor device.

As shown in FIGS. 4A-4G, the circuit structure 400 of the circuit 102 is similar to the circuit structure 200 of the circuit 102 illustrated in FIGS. 2A-2G. For example, in the circuit structure 400 of the circuit 102, the transistors 104 and 106 are laterally adjacent in the x-direction, the variable resistors 110 and 112 are laterally adjacent in the x-direction, the transistor 104 and the variable resistor 110 are laterally adjacent and electrically isolated by the isolation structure 208 in the y-direction, and the transistor 106 and the variable resistor 112 are laterally adjacent and electrically isolated by the isolation structure 208 in the y-direction.

However, in the circuit structure 400 of the circuit 102, the source/drain region 212b of the transistor 104 extends through the isolation structure 208 such that the contact 238 of the variable resistor 110 is merged with the source/drain region 212b. Similarly, the source/drain region 222a of the transistor 106 extends through the isolation structure 208 such that the contact 250 of the variable resistor 112 is merged with the source/drain region 222a.

The source/drain region 212b of the transistor 104 may be directly connected and merged with the contact 238 of the variable resistor 110, and the source/drain region 222a of the transistor 104 may be directly connected and merged with the contact 250 of the variable resistor 112, in implementations in which the lateral (y-direction) width (indicated in FIG. 4A as a dimension D4) of the circuit 102 in the circuit structure 400 is sufficient small. This reduces the manufacturing complexity for the circuit structure 400. However, in implementations in which the lateral width is large, such as in the circuit structure 200, the source/drain region 212b of the transistor 104 may be connected with the contact 238 of the variable resistor 110 by interconnect structures and metallization structures, and the source/drain region 222a of the transistor 104 may be connected with the contact 250 of the variable resistor 112 interconnect structures and metallization structures.

As indicated above, FIGS. 4A-4G are provided as an example. Other examples may differ from what is described with regard to FIGS. 4A-4G.

FIGS. 5A-5D are diagrams of an example circuit structure 500 of the circuit 102 described herein. In particular, the circuit structure 500 is an example of a circuit structure implementation of the circuit 102 in which the circuit 102 is implemented in a semiconductor device.

As shown in FIGS. 5A-5D, the circuit structure 500 of the circuit 102 is similar to the circuit structure 200 of the circuit 102 illustrated in FIGS. 2A-2G. For example, in the circuit structure 500 of the circuit 102, the transistors 104 and 106 are laterally adjacent in the x-direction, the source/drain region 212b is electrically coupled to the variable resistor 110, the source/drain regions 212a and 222a are electrically coupled to the variable resistor 112, and the gate structures 210 and 220 are electrically coupled together.

However, in the circuit structure 500, the variable resistors 110 and 112 are located on laterally opposing sides of the circuit 102 in the y-direction, as opposed to being located adjacent to each other as in the circuit structure 200. For example, the variable resistor 110 may be located laterally adjacent to a first side of the transistor 104 in the x-direction, a second (opposing) side of the transistor 104 may be located laterally adjacent to a first side of the transistor 106 in the x-direction, and the variable resistor 112 may be located laterally adjacent to a second (opposing) side of the transistor 106 in the x-direction. Thus, the variable resistor 112, the transistor 106, the transistor 106, and the variable resistor 110 are arranged in the x-direction in the circuit structure 500.

Moreover, the semiconductor region 244 and the semiconductor layer 246 of the variable resistor 110 extend in the y-direction in the circuit structure 500 as opposed to in the x-direction in the circuit structure 200. Similarly, the semiconductor region 258 and the semiconductor layer 260 of the variable resistor 112 extend in the y-direction in the circuit structure 500 as opposed to in the x-direction in the circuit structure 200.

In addition, the gate structures 210 and 220 may be electrically coupled together by a plurality of gate connector segments, including a first gate connector segment 224a coupled to first ends of the gate structures 210 and 220, and a second gate connector segment 224b coupled to second ends of the gate structures 210 and 220 opposing the first ends in the y-direction. This results in the circuit structure 500 including an O-shaped unified gate structure, corresponding to the gate structures 210, 220, and the gate connector segments 224a, 224b. Thus, the circuit structure 500 may be referred to as an O-shaped dynamic current mirror (ODCM).

FIG. 5B illustrates a cross-section view of the circuit structure 500 along the line G-G′ in FIG. 5A, which is along the transistors 104, 106, and the variable resistors 110, 112 in the x-direction. As shown in FIG. 5B, the transistor 104 and the variable resistor 110 may be spaced apart by a portion of the circuit isolation structure 204 in the x-direction. Similarly, the transistor 106 and the variable resistor 112 may be spaced apart by a portion of the circuit isolation structure 204 in the x-direction. The transistors 104 and 106 may be spaced apart by the isolation structure 206 in the x-direction.

FIG. 5C illustrates a cross-section view of the circuit structure 500 along the line H-H′ in FIG. 5A, which is along the transistors 104, 106, and the variable resistors 110, 112 in the x-direction. As shown in FIG. 5C, the interconnect structures 214, 216, and 242, and the metallization structure 218, may electrically couple the transistor 104 and the variable resistor 110. In particular, the gate structure 210 and the source/drain region 212b of the transistor 104 may be electrically coupled to the semiconductor region 244 of the variable resistor 110 through the interconnect structures 214, 216, and 242, and the metallization structure 218.

As further shown in FIG. 5C, the interconnect structures 226 and 256, and the metallization structure 228, may electrically couple the transistor 104 and the variable resistor 112. In particular, the source/drain region 212a of the transistor 104 may be electrically coupled to the semiconductor region 258 of the variable resistor 112 through the interconnect structures 226 and 256, and the metallization structure 228. The metallization structure 228 may extend over the transistor 106 in the y-direction.

FIG. 5D illustrates a cross-section view of the circuit structure 500 along the line I-I′ in FIG. 5A, which is along the transistors 104, 106, and the variable resistors 110, 112 in the x-direction. As further shown in FIG. 5D, the interconnect structures 230 and 254, and a metallization structure 232, may electrically couple the transistor 106 and the variable resistor 112. In particular, the source/drain region 222a of the transistor 106 may be electrically coupled to the semiconductor region 258 of the variable resistor 112 through the interconnect structures 230 and 254, and the metallization structure 232. The metallization structure 232 may extend over the transistor 106 in the y-direction.

As indicated above, FIGS. 5A-5D are provided as an example. Other examples may differ from what is described with regard to FIGS. 5A-5D.

FIGS. 6A-6D are diagrams of an example circuit structure 600 of the circuit 102 described herein. In particular, the circuit structure 600 is an example of a circuit structure implementation of the circuit 102 in which the circuit 102 is implemented in a semiconductor device.

As shown in FIGS. 6A-6D, the circuit structure 600 of the circuit 102 is similar to the circuit structure 500 of the circuit 102 illustrated in FIGS. 5A-5D. For example, in the circuit structure 600 of the circuit 102, the transistors 104 and 106 are laterally adjacent in the x-direction, the variable resistor 110 is laterally adjacent to the transistor 104 in the x-direction, and the variable resistor 112 is laterally adjacent to the transistor 106 in the x-direction.

Moreover, the variable resistors 110 and 112 extend in the y-direction, and the gate structures 210 and 220 are coupled together by gate connector segments 224a and 224b at opposing ends of the gate structures 210 and 220.

However, in the circuit structure 600 of the circuit 102, the source/drain region 212b of the transistor 104 extends across the circuit isolation structure 204 such that the contact 238 of the variable resistor 110 is merged with the source/drain region 212b. The source/drain region 212b of the transistor 104 may be directly connected and merged with the contact 238 of the variable resistor 110 in implementations in which the lateral (y-direction) width (indicated in FIG. 6A as a dimension D5) of the circuit 102 in the circuit structure 600 is sufficient small. This reduces the manufacturing complexity for the circuit structure 600.

However, in implementations in which the lateral width is large, such as in the circuit structure 500, the source/drain region 212b of the transistor 104 may be connected with the contact 238 of the variable resistor 110 by interconnect structures and metallization structures.

As indicated above, FIGS. 6A-6D are provided as an example. Other examples may differ from what is described with regard to FIGS. 6A-6D.

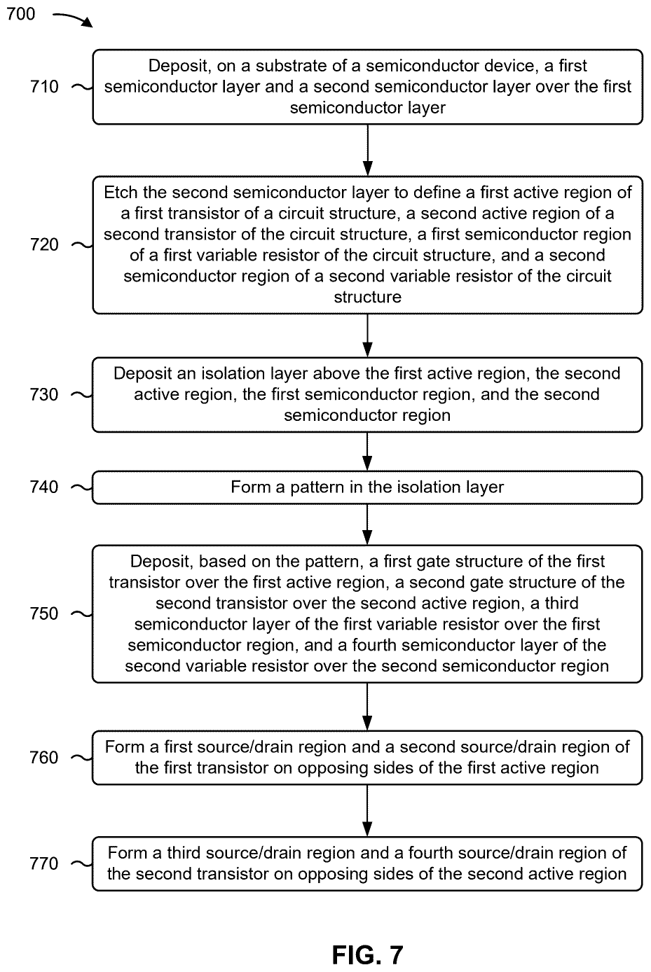

FIG. 7 is a flowchart of an example process 700 associated with forming a semiconductor device described herein. In some implementations, one or more process blocks of FIG. 7 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 7, process 700 may include depositing, on a substrate of a semiconductor device, a first semiconductor layer and a second semiconductor layer over the first semiconductor layer (block 710). For example, one or more semiconductor processing tools may be used to deposit, on a substrate (e.g., a substrate layer 264) of a semiconductor device (e.g., a semiconductor device 302), a first semiconductor layer (e.g., a semiconductor layer 266) and a second semiconductor layer (e.g., a semiconductor layer 304) over the first semiconductor layer, as described herein.

As further shown in FIG. 7, process 700 may include etching the second semiconductor layer to define a first active region of a first transistor of a circuit structure, a second active region of a second transistor of the circuit structure, a first semiconductor region of a first variable resistor of the circuit structure, and a second semiconductor region of a second variable resistor of the circuit structure (block 720). For example, one or more semiconductor processing tools may be used to etch the second semiconductor layer to define a first active region (e.g., an active region 202a) of a first transistor (e.g., a transistor 104) of a circuit structure (e.g., a circuit structure of a circuit 102), a second active region (e.g., an active region 202b) of a second transistor (e.g., a transistor 106) of the circuit structure, a first semiconductor region (e.g., a semiconductor region 244) of a first variable resistor (e.g., a variable resistor 110) of the circuit structure, and a second semiconductor region (e.g., a semiconductor region 258) of a second variable resistor (e.g., a variable resistor 112) of the circuit structure, as described herein.

As further shown in FIG. 7, process 700 may include depositing an isolation layer above the first active region, the second active region, the first semiconductor region, and the second semiconductor region (block 730). For example, one or more semiconductor processing tools may be used to deposit an isolation layer (e.g., an isolation layer 272) above the first active region, the second active region, the first semiconductor region, and the second semiconductor region, as described herein.

As further shown in FIG. 7, process 700 may include forming a pattern in the isolation layer (block 740). For example, one or more semiconductor processing tools may be used to form a pattern (e.g., a pattern 306) in the isolation layer, as described herein.

As further shown in FIG. 7, process 700 may include depositing, based on the pattern, a first gate structure of the first transistor over the first active region, a second gate structure of the second transistor over the second active region, a third semiconductor layer of the first variable resistor over the first semiconductor region, and a fourth semiconductor layer of the second variable resistor over the second semiconductor region (block 750). For example, one or more semiconductor processing tools may be used to deposit, based on the pattern, a first gate structure (e.g., a gate structure 210) of the first transistor over the first active region, a second gate structure (e.g., a gate structure 220) of the second transistor over the second active region, a third semiconductor layer (e.g., a semiconductor layer 246) of the first variable resistor over the first semiconductor region, and a fourth semiconductor layer (e.g., a semiconductor layer 260) of the second variable resistor over the second semiconductor region, as described herein.

As further shown in FIG. 7, process 700 may include forming a first source/drain region and a second source/drain region of the first transistor on opposing sides of the first active region (block 760). For example, one or more semiconductor processing tools may be used to form a first source/drain region (e.g., a source/drain region 212a) and a second source/drain region (e.g., a source/drain region 212b) of the first transistor on opposing sides of the first active region, as described herein.

As further shown in FIG. 7, process 700 may include forming a third source/drain region and a fourth source/drain region of the second transistor on opposing sides of the second active region (block 770). For example, one or more semiconductor processing tools may be used to form a third source/drain region (e.g., a source/drain region 222a) and a fourth source/drain region (e.g., a source/drain region 222b) of the second transistor on opposing sides of the second active region, as described herein.

Process 700 may include additional implementations, such as any single implementation or any combination of implementations described below and/or in connection with one or more other processes described elsewhere herein.

In a first implementation, depositing the first gate structure, the second gate structure, the third semiconductor layer, and the fourth semiconductor layer includes epitaxially growing the first gate structure, the second gate structure, the third semiconductor layer, and the fourth semiconductor layer.

In a second implementation, alone or in combination with the first implementation, process 700 includes forming a layer of interconnect structures (e.g., interconnect structures 214, 216, 226, 230, 234, 240, 242, 254, and/or 256), and forming a layer of metallization structures (e.g., metallization structures 218, 228, and/or 232) over the layer of interconnect structures, where one or more first interconnect structures, of the layer of interconnect structures, and one or more first metallization structures, of the layer of metallization structures, electrically couple the first variable resistor to the first transistor and the second transistor, and where one or more second interconnect structures, of the layer of interconnect structures, and one or more second metallization structures, of the layer of metallization structures, electrically couple the second variable resistor to the second transistor.

In a third implementation, alone or in combination with one or more of the first and second implementations, process 700 includes depositing a first isolation structure (e.g., an isolation structure 206) such that the first isolation structure is between the first active region and the second active region, and between the first semiconductor region and the second semiconductor region, and depositing a second isolation structure (e.g., an isolation structure 208) such that the second isolation structure is between the first active region and the first semiconductor region, and between the second active region and the second semiconductor region.

In a fourth implementation, alone or in combination with one or more of the first through third implementations, process 700 includes depositing, based on the pattern, one or more gate connector segments (e.g., gate connector segments 224, 224a, and/or 224b) that electrically couple the first gate structure and the second gate structure.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

In this way, a semiconductor device may be manufactured to include a semiconductor structure in which a current mirror circuit is implemented. The semiconductor structure may be manufactured so that the current mirror circuit includes one or more variable resistor structures. For example, the semiconductor structure may be manufactured so that the current mirror circuit includes a variable reference resistor structure and/or a variable output resistor structure. The variable resistor structures may be manufactured using gallium (Ga) based HEMT-like processes. This enables the manufacturing of the variable resistor structures to be easily integrated with manufacturing of the transistors of the current mirror circuit, which reduces manufacturing process complexity, cost, and/or time for integrating the variable resistor structures into the current mirror circuit.

As described in greater detail above, some implementations described herein provide a circuit structure. The circuit structure includes a first transistor. The first transistor includes a first gate structure, a first source/drain region, and a second source/drain region. The first source/drain region and the second source/drain region are adjacent to opposing sides of the first gate structure in a first lateral direction. The first gate structure, the first source/drain region, and the second source/drain region extend in a second lateral direction. The second source/drain region and the first gate structure are electrically coupled together. The circuit structure includes a second transistor adjacent to the first transistor in the first lateral direction. The second transistor includes a second gate structure, a third source/drain region, and a fourth source/drain region. The third source/drain region and the fourth source/drain region are adjacent to opposing sides of the second gate structure in the first lateral direction. The second gate structure, the third source/drain region, and the fourth source/drain region extend in the second lateral direction. The first gate structure and the second gate structure are electrically coupled together. The circuit structure includes a variable resistor electrically coupled to the second source/drain region and the first gate structure. The variable resistor includes a first semiconductor layer that contains a first semiconductor material. The variable resistor includes a second semiconductor layer, over the first semiconductor layer, that contains a second semiconductor material that is different than the first semiconductor material.

As described in greater detail above, some implementations described herein provide a semiconductor device. The semiconductor device includes a first semiconductor layer that contains a first semiconductor material. The semiconductor device includes a first transistor above the first semiconductor layer. The semiconductor device includes a second transistor above the first semiconductor layer and adjacent to the first transistor. The semiconductor device includes a first variable resistor electrically coupled to the first transistor and the second transistor. The first variable resistor includes a first semiconductor region that contains a second semiconductor material that is different than the first semiconductor material. The first variable resistor includes a third semiconductor layer, over the second semiconductor region, that contains a third semiconductor material that is different than the second semiconductor material. The semiconductor device includes a second variable resistor electrically coupled to the second transistor. The second variable resistor includes a second semiconductor region that contains the second semiconductor material. The second variable resistor includes a second semiconductor layer, over the first semiconductor region, that contains the third semiconductor material.

As described in greater detail above, some implementations described herein provide a method. The method includes depositing, on a substrate of a semiconductor device, a first semiconductor layer and a second semiconductor layer over the first semiconductor layer. The method includes etching the second semiconductor layer to define a first active region of a first transistor of a circuit structure, a second active region of a second transistor of the circuit structure, a first semiconductor region of a first variable resistor of the circuit structure, and a second semiconductor region of a second variable resistor of the circuit structure. The method includes depositing an isolation layer above the first active region, the second active region, the first semiconductor region, and the second semiconductor region. The method includes forming a pattern in the isolation layer. The method includes depositing, based on the pattern, a first gate structure of the first transistor over the first active region, a second gate structure of the second transistor over the second active region, a third semiconductor layer of the first variable resistor over the first semiconductor region, and a fourth semiconductor layer of the second variable resistor over the second semiconductor region. The method includes forming a first source/drain region and a second source/drain region of the first transistor on opposing sides of the first active region. The method includes forming a third source/drain region and a fourth source/drain region of the second transistor on opposing sides of the second active region.

The terms “approximately” and “substantially” can indicate a value of a given quantity that varies within 5% of the value (e.g., +1%, +2%, +3%, +4%, +5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A circuit structure, comprising:
a first transistor, comprising:
a first gate structure;
a first source/drain region; and
a second source/drain region,
wherein the first source/drain region and the second source/drain region are adjacent to opposing sides of the first gate structure in a first lateral direction,
wherein the first gate structure, the first source/drain region, and the second source/drain region extend in a second lateral direction, and
wherein the second source/drain region and the first gate structure are electrically coupled together;
a second transistor, adjacent to the first transistor in the first lateral direction, comprising:
a second gate structure;
a third source/drain region; and
a fourth source/drain region,
wherein the third source/drain region and the fourth source/drain region are adjacent to opposing sides of the second gate structure in the first lateral direction,
wherein the second gate structure, the third source/drain region, and the fourth source/drain region extend in the second lateral direction, and
wherein the first gate structure and the second gate structure are electrically coupled together; and
a variable resistor, electrically coupled to the second source/drain region and the first gate structure, comprising:
a first semiconductor layer comprising a first semiconductor material; and
a second semiconductor layer, over the first semiconductor layer, comprising a second semiconductor material that is different than the first semiconductor material.

2. The circuit structure of claim 1, wherein the first semiconductor material comprises aluminum gallium nitride (AlGaN); and
wherein the second semiconductor material comprises gallium nitride (GaN) doped with one or more types of dopants.

3. The circuit structure of claim 1, further comprising:
a bias contact coupled to the second semiconductor layer.

4. The circuit structure of claim 1, wherein the variable resistor is laterally between a first ohmic contact and a second ohmic contact in the first lateral direction;
wherein the first ohmic contact is adjacent to an end of the first source/drain region in the second lateral direction; and
wherein the second ohmic contact is adjacent to an end of the second source/drain region in the second lateral direction.

5. The circuit structure of claim 4, further comprising:
an isolation structure between the first ohmic contact and the end of the first source/drain region in the second lateral direction, and between the second ohmic contact and the end of the second source/drain region in the second lateral direction.

6. The circuit structure of claim 1, wherein the variable resistor is laterally between an ohmic contact and a portion of the second source/drain region in the first lateral direction; and
wherein the ohmic contact is adjacent to the first source/drain region in the second lateral direction.

7. The circuit structure of claim 6, further comprising:
an isolation structure between the ohmic contact and the first source/drain region in the second lateral direction.

8. The circuit structure of claim 1, wherein the first gate structure is adjacent to a first side of the second source/drain region; and
wherein the variable resistor is adjacent to a second side of the second source/drain region opposing the first side in the first lateral direction.

9. A semiconductor device, comprising:
a first semiconductor layer comprising a first semiconductor material;
a first transistor above the first semiconductor layer;
a second transistor above the first semiconductor layer and adjacent to the first transistor;
a first variable resistor, electrically coupled to the first transistor and the second transistor, comprising:
a first semiconductor region comprising a second semiconductor material that is different than the first semiconductor material; and
a second semiconductor layer, over the first semiconductor region, comprising a third semiconductor material that is different than the second semiconductor material; and
a second variable resistor, electrically coupled to the second transistor, comprising:
a second semiconductor region comprising the second semiconductor material; and
a third semiconductor layer, over the second semiconductor region, comprising the third semiconductor material.

10. The semiconductor device of claim 9, wherein the first transistor comprises:
a third semiconductor region comprising the second semiconductor material;
a first two-dimensional electron gas (2DEG) channel between the first semiconductor layer and the third semiconductor region;
a first gate structure above the third semiconductor region;
a first source/drain region adjacent to the third semiconductor region; and
a second source/drain region adjacent to the third semiconductor region,
wherein the second source/drain region and the first gate structure are electrically coupled together.

11. The semiconductor device of claim 10, wherein the second transistor comprises:
a fourth semiconductor region comprising the second semiconductor material;
a second 2DEG channel between the first semiconductor layer and the fourth semiconductor region;
a second gate structure above the fourth semiconductor region;
a third source/drain region adjacent to the fourth semiconductor region; and
a fourth source/drain region adjacent to the fourth semiconductor region,
wherein the first gate structure and the second gate structure are electrically coupled together, and
wherein the second source/drain region and the second gate structure are electrically coupled together.

12. The semiconductor device of claim 11, wherein the second source/drain region, the first gate structure, and the second gate structure are electrically coupled to the first variable resistor.

13. The semiconductor device of claim 11, wherein the third source/drain region is electrically coupled to the second variable resistor.

14. The semiconductor device of claim 11, wherein the first gate structure and the second gate structure comprise the third semiconductor material.

15. The semiconductor device of claim 9, wherein the first semiconductor material comprises gallium nitride (GaN);
wherein the second semiconductor material comprises aluminum gallium nitride (AlGaN); and
wherein the third semiconductor material comprises doped gallium nitride.

16. A method, comprising:
depositing, on a substrate of a semiconductor device, a first semiconductor layer and a second semiconductor layer over the first semiconductor layer;
etching the second semiconductor layer to define:
a first active region of a first transistor of a circuit structure,
a second active region of a second transistor of the circuit structure,
a first semiconductor region of a first variable resistor of the circuit structure, and
a second semiconductor region of a second variable resistor of the circuit structure;
depositing an isolation layer above the first active region, the second active region, the first semiconductor region, and the second semiconductor region;
forming a pattern in the isolation layer;
depositing, based on the pattern:
a first gate structure of the first transistor over the first active region,
a second gate structure of the second transistor over the second active region,
a third semiconductor layer of the first variable resistor over the first semiconductor region, and
a fourth semiconductor layer of the second variable resistor over the second semiconductor region;
forming a first source/drain region and a second source/drain region of the first transistor on opposing sides of the first active region; and
forming a third source/drain region and a fourth source/drain region of the second transistor on opposing sides of the second active region.

17. The method of claim 16, wherein depositing the first gate structure, the second gate structure, the third semiconductor layer, and the fourth semiconductor layer comprises:
epitaxially growing the first gate structure, the second gate structure, the third semiconductor layer, and the fourth semiconductor layer.

18. The method of claim 16, further comprising:
forming a layer of interconnect structures; and
forming a layer of metallization structures over the layer of interconnect structures,
wherein one or more first interconnect structures, of the layer of interconnect structures, and one or more first metallization structures, of the layer of metallization structures, electrically couple the first variable resistor to the first transistor and the second transistor, and
wherein one or more second interconnect structures, of the layer of interconnect structures, and one or more second metallization structures, of the layer of metallization structures, electrically couple the second variable resistor to the second transistor.

19. The method of claim 16, further comprising:
depositing a first isolation structure such that the first isolation structure is between the first active region and the second active region, and between the first semiconductor region and the second semiconductor region,
wherein the first isolation structure comprises amorphous isolation achieved by implanting oxygen; and
depositing a second isolation structure such that the second isolation structure is between the first active region and the first semiconductor region, and between the second active region and the second semiconductor region.

20. The method of claim 16, further comprising:
depositing, based on the pattern, one or more gate connector segments that electrically couple the first gate structure and the second gate structure.
